(19) United States
(12) Patent Application Publication
(10) Pub. No.: US 2024/0347431 A1
(43) Pub. Date: Oct. 17, 2024

(54) SEMICONDUCTOR DEVICE

(71) Applicant: FUJI ELECTRIC CO., LTD., Kawasaki-shi (JP)

(72) Inventors: Masaoki MIYAKOSHI, Matsumoto-city (JP); Rikihiro MARUYAMA, Matsumoto-city (JP)

(73) Assignee: FUJI ELECTRIC CO., LTD., Kawasaki-shi (JP)

(21) Appl. No.: 18/754,544

(22) Filed: Jun. 26, 2024

Related U.S. Application Data
(63) Continuation of application No. PCT/JP2023/020488, filed on Jun. 1, 2023.

(30) Foreign Application Priority Data
Jul. 13, 2022 (JP) 2022-112216

(51) Int. Cl. H01L 23/498

(52) U.S. Cl. CPC H01L 23/49811

(57) ABSTRACT

A sleeve is disposed on a conductive layer of an insulated circuit substrate of a semiconductor device, and includes a cylindrical portion with a through hole and a flange provided at an one end of the cylindrical portion. The flange includes a plurality of protrusions and a plurality of recesses that each extend a radial direction of the cylindrical portion from the opening edge of the through hole to an outer circumferential periphery of the flange, and are disposed alternate with one another in a circumferential direction of the flange. Each protrusion has a top surface and each recess has a bottom surface that are continuous with the opening edge of the through hole so as to each have a single flat surface parallel to the radial direction.

### CROSS-REFERENCE TO RELATED APPLICATION

This application is a continuation application of International Application PCT/JP2023/020488 filed on Jun. 1, 2023, which designated the U.S., which claims priority to Japanese Patent Application No. 2022-112216, filed on Jul. 13, 2022, the entire contents of which are incorporated herein by reference.

### BACKGROUND OF THE INVENTION

### 1. Field of the Invention

The embodiments discussed herein relate to a semiconductor device.

### 2. Background of the Related Art

There are known a technique of soldering a contact element having a cylindrical shaft, into which a contact pin is to be inserted, and having a flange provided at an end of the shaft, to a conductor area of a circuit carrier and a technique of providing a plurality of webs along the circumference of the flange on an end face of the flange such that the webs project by a predetermined height from the flat plane of the end face (U.S. Patent Application Publication No. 2009/0194884).

Further, there is known a technique in which, with respect to a contact component having a hollow hole, into which an external terminal is to be fit, and having at a lower end thereof a flange, which is to be soldered to a metal region provided on an insulating substrate, a flat bottom surface and a concave portion extending from an inner circumferential edge of a cylindrical portion of the contact component to an outer circumferential edge of the flange are provided in an end face of the flange, and a cut-out portion such as a chamfered portion, a step portion, or recessed surface portion is formed at a lower end inside the cylindrical portion (International Publication Pamphlet No. WO 2014/148319).

Still further, there are known a technique in which, with respect to a cylindrical component to be soldered to a circuit layer of an insulated substrate, a plurality of projections are provided on a flange connected to an end of a cylindrical portion of the cylindrical component in such a manner that the distances between adjacent projections are greater than the inner diameter of the cylindrical portion, and a technique in which the plurality of projections are provided, not on a curved surface portion at the inner circumferential side of the flange that is connected to the cylindrical portion but on a disc-shaped flat portion at the outer circumferential side of the flange that is continuous with the curved surface portion, in such a manner that the projections are in contact with the outer circumference of the flange (Japanese Laid-open Patent Publication No. 2017-011221).

In a semiconductor device in which a cylindrical component called a sleeve, into which an external terminal is to be inserted, is connected to a conductive layer of an insulated circuit substrate including an insulating board and the conductive layer disposed on the principal surface of the insulating board, one end of the external terminal is inserted into the hole of the sleeve, for example, with an automatic insertion machine. Prior to the insertion of the external terminal with the automatic insertion machine, binarization processing is first performed on an image of the sleeve captured from the sleeve side of the insulated circuit substrate to detect the center position of the hole of the sleeve. Then, the one end of the external terminal is inserted into the detected center position of the hole of the sleeve with the automatic insertion machine.

Typically, the sleeve includes a cylindrical portion with the hole and flanges provided at both opening ends of the cylindrical portion. Conventionally, taking into consideration the soldering of a flange to the conductive layer of the insulated circuit substrate, such surface irregularities as described above may be formed in the end face of the flange of the sleeve, which is subjected to image acquisition and its subsequent binarization processing. In this case, however, when an image of the sleeve is captured from the flange side, the center position of the hole of the sleeve detected through the binarization processing may be deviated from the actual center position, depending on the surface irregularities formed in the end face and the shadows created by the surface irregularities. If the one end of the external terminal is inserted into the deviated center position of the hole, detected through the binarization processing, with the automatic insertion device, the external terminal may be inserted in an inclined position into the sleeve.

If thereafter the other end of the external terminal opposite to the end thereof inserted into the sleeve is inserted in a component such as a circuit substrate, such an inclination of the external terminal may cause damage, insertion failure in which the external terminal is not properly inserted into a predetermined insertion position, or another due to a collision of the other end that is misaligned.

### SUMMARY OF THE INVENTION

According to an aspect, there is provided a semiconductor device, including: an insulated circuit substrate including an insulating board and a conductive layer disposed on a principal surface of the insulating board; and a sleeve connected to the conductive layer, wherein the sleeve includes a cylindrical portion with a through hole extending in an axial direction of the cylindrical portion that is perpendicular to the principal surface of the insulating board, and a flange provided at one end of the cylindrical portion, surrounding an opening edge of the through hole, wherein the flange includes a plurality of protrusions each protruding in the axial direction away from the insulated circuit substrate, and extending in a radial direction of the cylindrical portion from the opening edge of the through hole to an outer circumferential periphery of the flange, and a plurality of recesses each recessed in the axial direction toward the insulated circuit substrate, and extending in the radial direction from the opening edge of the through hole to the outer circumferential periphery of the flange, the plurality f recesses being provided respectively alternating with the plurality of protrusions in a circumferential direction of the flange, wherein each of the plurality of protrusions has a top surface that is continuous from the opening edge of the through hole so as to have a single flat surface parallel to the radial direction, and wherein each of the plurality of recesses has a bottom surface that is continuous with the opening edge of the through hole so as to have a single flat surface parallel to the radial direction.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a view for describing an example semiconductor device (part 1);

FIG. 2 is a view for describing the example semiconductor device (part 2);

FIGS. 3A and 3B are views for describing insertion of an external terminal into a sleeve mounted on an insulated circuit substrate (part 1);

FIGS. 4A and 4B are views for describing insertion of an external terminal into a sleeve mounted on an insulated circuit substrate (part 2);

FIGS. 5A and 5B are views for describing insertion of an external terminal into a sleeve mounted on an insulated circuit substrate (part 3);

FIGS. 6A and 6B are views for describing insertion of an external terminal into a sleeve mounted on an insulated circuit substrate (part 4);

FIG. 7 is a view for describing an example sleeve according to a first embodiment (part 1);

FIGS. 8A and 8B are views for describing the example sleeve according to the first embodiment (part 2);

FIG. 9 is a view for describing an example state of a sleeve being imaged according to the first embodiment;

FIGS. 10A and 10B are views for describing an example sleeve according to a second embodiment;

FIGS. 11A and 11B are views for describing an example sleeve according to a third embodiment;

FIG. 12 is a view illustrating an example sleeve according to a fourth embodiment (part 1);

FIGS. 13A and 13B are views illustrating the example sleeve according to the fourth embodiment (part 2);

FIGS. 14A and 14B are views illustrating an example sleeve according to a fifth embodiment;

FIGS. 15A and 15B are views illustrating an example sleeve according to a sixth embodiment; and

FIG. 16 is a view for describing an example semiconductor device according to a seventh embodiment.

### DETAILED DESCRIPTION OF THE INVENTION

First, an example configuration of a semiconductor device will be described.

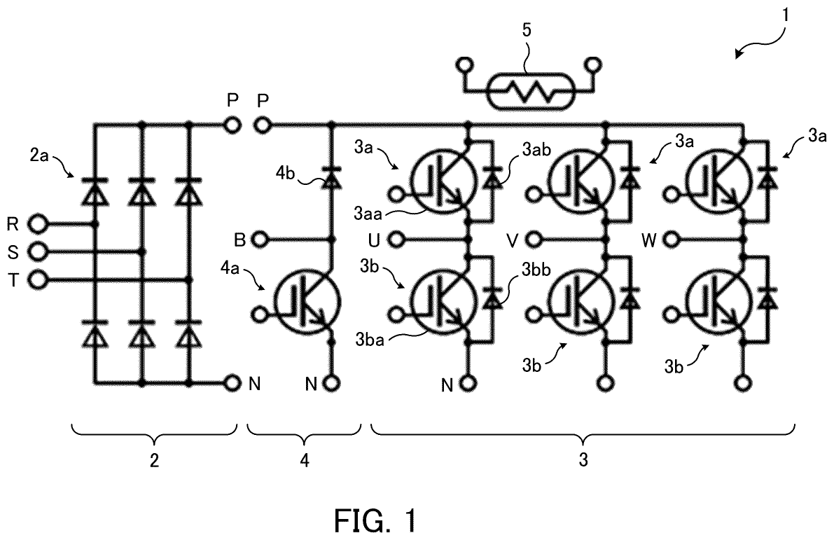

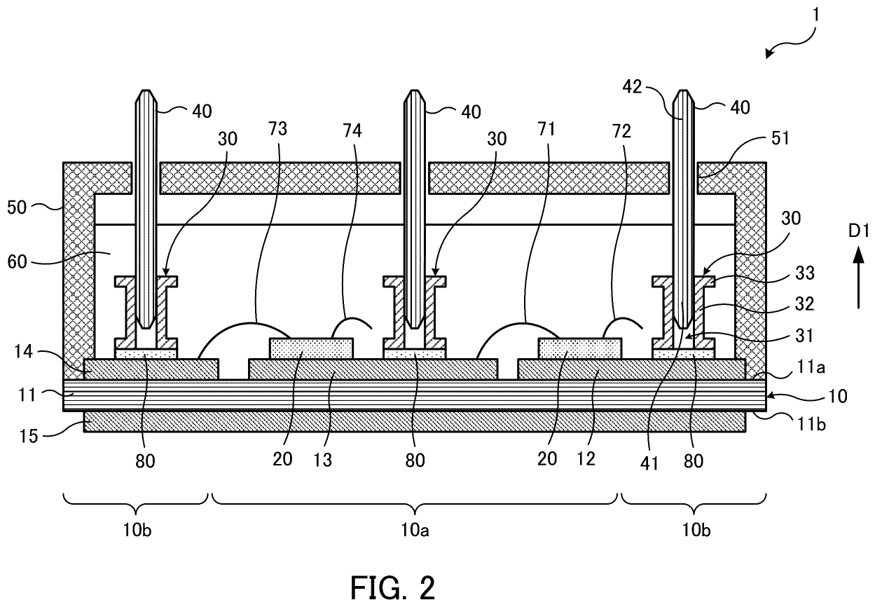

FIGS. 1 and 2 are views for describing an example semiconductor device. FIG. 1 is a circuit diagram of the example semiconductor device. FIG. 2 is a main-part sectional view schematically illustrating the example semiconductor device.

FIG. 1 is a circuit diagram of a semiconductor device 1 including a three-phase voltage inverter circuit. The semiconductor device 1 illustrated in FIG. 1 is an example of a power integrated module (PIM) including a voltage-type pulse width modulation (PWM)-controlled inverter circuit. The semiconductor device 1 includes a converter circuit section 2, an inverter circuit section 3, a regenerative power discharging circuit section 4 (dynamic brake section), and a thermistor 5.

The converter circuit section 2 includes a diode bridge circuit 2a for the R-phase, S-phase, and T-phase of a three-phase alternating current power supply and is designed to rectify an alternating current to a direct current.

The inverter circuit section 3 converts the direct current to a three-phase alternating current of U-phase, V-phase, and W-phase with PWM control.

The inverter circuit section 3 includes a semiconductor element 3a and a semiconductor element 3b that are connected in series. For each of the semiconductor element 3a and semiconductor element 3b, a switch element such as an insulated gate bipolar transistor (IGBT) or a metal-oxide-semiconductor field-effect transistor (MOSFET) is used. A diode element such as a free-wheeling diode (FWD) or Schottky barrier diode (SBD) may be connected to a switch element used in each of the semiconductor element 3a and semiconductor element 3b. Referring to the example of FIG. 1, a reverse conducting (RC)-IGBT in which an IGBT 3aa and an FWD 3ab are connected to each other is used as the semiconductor element 3a, and an RC-IGBT in which an IGBT 3ba and an FWD 3bb are connected to each other is used as the semiconductor element 3b.

In the semiconductor element 3a, the collector of the IGBT 3aa and the cathode of the FWD 3ab are connected to each other, and the emitter of the IGBT 3aa and the anode of the FWD 3ab are connected to each other. In the semiconductor element 3b, the collector of the IGBT 3ba and the cathode of the FWD 3bb are connected to each other, and the emitter of the IGBT 3ba and the anode of the FWD 3bb are connected to each other. The emitter of the IGBT 3aa of the semiconductor element 3a and the collector of the IGBT 3ba of the semiconductor element 3b are connected to each other. The semiconductor element 3a forms the upper arm of the inverter circuit section 3. The semiconductor element 3b forms the lower arm of the inverter circuit section 3. The collector of the semiconductor element 3a is connected to a positive electrode (P) terminal. The emitter of the semiconductor element 3b is connected to a negative electrode (N) terminal. A connection node between the semiconductor element 3a and the semiconductor element 3b that are connected in series is connected to an output terminal that outputs an output current.

In this connection, the semiconductor element 3a forming the upper arm is not limited to the one including one set of IGBT 3aa and FWD 3ab, and a plurality of sets of IGBT 3aa and FWD 3ab may be connected in parallel. The semiconductor element 3b forming the lower arm is not limited to the one including one set of IGBT 3ba and FWD 3bb, and a plurality of sets of IGBT 3ba and FWD 3bb may be connected in parallel.

The inverter circuit section 3 is formed by connecting three sets each including the semiconductor element 3a and semiconductor element 3b that respectively form the upper and lower arms as described above in parallel between the PN terminals. The output terminals of the three sets of semiconductor element 3a and semiconductor element 3b correspond to the U-phase, V-phase, and W-phase output nodes of the inverter circuit section 3 and are connected to a load, for example, a motor.

In this connection, the semiconductor elements 3a each including the IGBT 3aa and FWD 3ab and the semiconductor elements 3b each including the IGBT 3ba and FWD 3bb are illustrated as an example. Other switch elements such as MOSFETs may be used in place of the IGBT 3aa and IGBT 3ba, and other diode elements such as SBDs may be used in place of the FWD 3ab and FWD 3bb.

In addition, the regenerative power discharging circuit section 4 includes a semiconductor element 4a such as an IGBT and a diode 4b, and is designed to suppress a voltage increase caused by an energy produced during the regenerative operation of the motor.

The thermistor 5 is built in the module in such a manner as to be insulated from the main circuit, and is used for temperature detection in order to prevent damage caused by abnormal heating or the like due to an increase in the loss of the IGBTs.

For example, the semiconductor device 1 that implements the above circuit may have a configuration as illustrated in FIG. 2.

The semiconductor device 1 (also called a “semiconductor module”) exemplified in FIG. 2 includes an insulated circuit substrate 10, semiconductor elements 20, sleeves 30, external terminals 40, a case 50, and a sealing resin 60.

The insulated circuit substrate 10 includes an insulating board 11, conductive layers 12, 13, and 14 disposed on a principal surface 11a of the insulating board 11, and a conductive layer 15 disposed on a principal surface 11b of the insulating board 11 opposite to the principal surface 11a. As the insulating board 11, a board made of alumina, composite ceramics containing alumina as a main component, aluminum nitride, silicon nitride, or another material is used. For the conductive layers 12, 13, 14, and 15, a conductive material such as copper is used. For example, as the insulated circuit substrate 10, a direct copper bonding (DCB) substrate is used. Alternatively, as the insulated circuit substrate 10, an active metal brazed (AMB) substrate or another substrate may be used. The semiconductor elements 20 and sleeves 30 are disposed at predetermined positions on the conductive layers 12, 13, and 14 provided on the principal surface 11a of the insulating board 11 of the insulated circuit substrate 10.

For example, in the case of the above-described inverter circuit section 3, semiconductor elements 20 that serve as the switch elements of the upper arm of the inverter circuit section 3 are disposed on the conductive layer 12, and semiconductor elements 20 that serve as the switch elements of the lower arm of the inverter circuit section 3 are disposed on the conductive layer 13. For each semiconductor element 20, a switch element such as an IGBT or MOSFET is used. For example, a diode element such as an FWD or SBD is integrated in each semiconductor element 20.

Each semiconductor element 20 of the inverter circuit section 3 has a collector electrode on one surface side and a gate electrode and an emitter electrode on the other surface side. In each semiconductor element 20 of the upper arm, the collector electrode is connected to the conductive layer 12 using a bonding material such as a solder or sintered material, and the emitter electrode is connected to the conductive layer 13 using a wire 71. Wires 72 that are connected to the gate electrodes of the semiconductor elements 20 of the upper arm are connected to a gate terminal provided on the case 50 or a conductive layer connected to the gate terminal, although it is not illustrated. The electrode collector of each semiconductor element 20 of the lower arm is connected to the conductive layer 13 using a bonding material such as a solder or sintered material, and the emitter electrode thereof is connected to the conductive layer 14 using a wire 73. Wires 74 that are connected to the gate electrodes of the semiconductor elements 20 of the lower arm are connected to a gate terminal provided on the case 50 or a conductive layer connected to the gate terminal, although it is not illustrated. The semiconductor elements 20 of the upper and lower arms are connected in series via the conductive layers 12, 13, and 14 and wires 71 and 73.

In this connection, FIG. 2 illustrates two semiconductor elements 20 in the sectional view, but the number of semiconductor elements 20 disposed on the insulated circuit substrate 10 is not limited thereto. In addition, the semiconductor elements 20 disposed on the insulated circuit substrate 10 are not limited to those used in the inverter circuit section 3 described as above, but also include those used in the regenerative power discharging circuit section 4 and others. In addition, the diode bridge circuit 2a used in the converter circuit section 2, the diode 4b used in the regenerative power discharging circuit section 4, and others may also be disposed on the insulated circuit substrate 10.

The sleeves 30 are disposed on the conductive layer 12, conductive layer 13, and conductive layer 14, for example. The sleeves 30 are made of a conductive material such as copper. Each sleeve 30 includes a cylindrical portion 32 with a hole (through hole) 31 extending in a direction DI perpendicular to each of the conductive layers 12, 13, and 14, and flanges 33 provided at both opening ends of the cylindrical portion 32. In each sleeve 30, the flange 33 on one opening end is bonded (i.e., soldered) to a predetermined one of the conductive layers 12, 13, and 14 via a solder 80. Each sleeve 30 is electrically connected to the predetermined one of the conductive layers 12, 13, and 14 via the solder 80.

The external terminals 40 are pin-shaped. A first end 41 of each pin-shaped external terminal 40 is inserted into the hole 31 of a sleeve 30 disposed on the insulated circuit substrate 10. The first end 41 of the external terminal 40 is inserted and fixed into the hole 31 of the sleeve 30 with press-insertion, fitting, or another technique. By inserting the first end 41 of the external terminal 40 into the hole 31 of the sleeve 30, the external terminal 40 is electrically connected to the sleeve 30. For example, in the case where a semiconductor element 20 is used in the inverter circuit section 3 as described above, an external terminal 40 inserted into a sleeve 30 disposed on the conductive layer 12 serves as a P terminal, an external terminal 40 inserted into a sleeve 30 disposed on the conductive layer 14 serves as an N terminal, and an external terminal 40 inserted into a sleeve 30 disposed on the conductive layer 13 serves as an output terminal (U-phase, V-phase, or W-phase).

In this connection, FIG. 2 illustrates three sleeves 30 and their corresponding external terminals 40 inserted therein in the sectional view. However, the number of sleeves 30 disposed on the insulated circuit substrate 10 and the number of external terminals 40 are not limited thereto.

The case 50 is provided to cover the side of the insulated circuit substrate 10 where the semiconductor elements 20 and sleeves 30 are disposed. For example, the case 50 is a resin case made of a resin material such as a poly-phenylene-sulfide (PPS) resin or the like. For example, the case 50 has a lower end thereof fixed to the edge of the insulated circuit substrate 10 using an adhesive or the like that is not illustrated. The case 50 has openings 51 at positions corresponding to the sleeves 30 disposed on the insulated circuit substrate 10. The external terminals 40 whose first ends 41 are inserted into the sleeves 30 pass through the openings 51 of the case 50, and the second ends 42 of the external terminals 40 opposite to the first ends 41 inserted into the sleeves 30 are drawn to the outside of the case 50.

The second ends 42 of the external terminals 40 drawn to the outside of the case 50 are inserted into connection holes of a circuit substrate, not illustrated, having the connection holes at positions corresponding to the external terminals 40, for example, and are connected to the circuit substrate. By doing so, the circuit substrate and the insulated circuit substrate 10 on which the semiconductor elements 20 and others are disposed are electrically connected via the external terminals 40. The second end 42 of each external terminal 40 may have such a press-fit structure as to enable the second end 42 to be inserted into and connected to the connection hole of the circuit substrate.

Inside the case 50, the insulated circuit substrate 10 and the sealing resin 60 sealing the semiconductor elements 20, sleeves 30, and others disposed on the insulated circuit substrate 10 are arranged. Examples of the sealing resin 60 include resin materials such as an epoxy resin and a phenolic resin, and a gel material such as silicone. The sealing resin 60 may contain an insulating filler such as silica. A plurality of kinds of materials may be used for the sealing resin 60. For example, the sealing resin 60 may be formed in a multilayer structure that has a lower layer made of, as a buffer coat material, a gel material such as silicone and an upper layer made of a resin material such as an epoxy resin.

In this connection, a base plate, a heat sink, a cooling unit, or another may be connected to the conductive layer 15 provided on an opposite side of the insulated circuit substrate 10 from the semiconductor elements 20, sleeves 30 and others. For example, the base plate, heat sink, cooling unit, or another is bonded to the conductive layer 15 using a thermally conductive material such as a thermal interface material (TIM), a solder, or a sintered material.

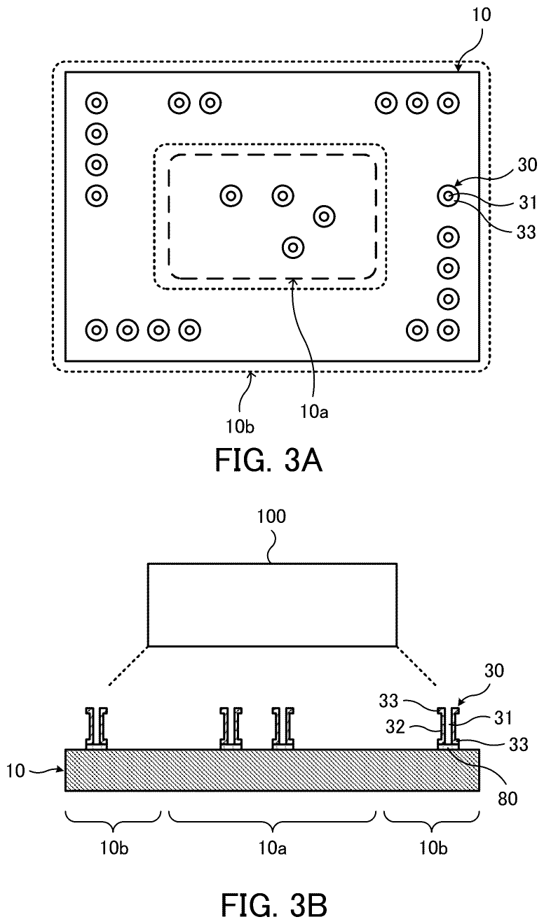

In assembling the semiconductor device 1 configured as above, the sleeves 30 are mounted on the insulated circuit substrate 10, and after the external terminals 40 are inserted into the sleeves 30, the case 50 and sealing resin 60 are arranged. For inserting the external terminals 40, an automatic insertion machine is used, for example. Before inserting the external terminals 40 with the automatic insertion machine, an image is obtained by imaging the sleeves 30 on the insulated circuit substrate 10, and then binarization processing of the image of the sleeves 30 is performed to detect the center positions of the holes 31 of the sleeves 30. Then, the first ends 41 of the external terminals 40 are inserted into thus detected center positions of the holes 31 of the sleeves 30 with the automatic insertion machine. The insertion of the external terminals 40 into the sleeves 30 disposed on the insulated circuit substrate 10 will be described with reference to FIGS. 3A to 6B.

FIGS. 3A to 6B include views for describing the insertion of an external terminal into a sleeve disposed on an insulated circuit substrate.

FIG. 3A is a main-part plan view schematically illustrating an example of the insulated circuit substrate 10 on which sleeves 30 are disposed. FIG. 3B is a main-part sectional view schematically illustrating the example of the insulated circuit substrate 10 on which the sleeves 30 are disposed, in an image acquisition step.

A plurality of sleeves 30 are disposed on predetermined conductive layers, not illustrated, of the insulated circuit substrate 10 using the solder 80. The sleeves 30 are disposed at different positions on the insulated circuit substrate 10. For example, the sleeves 30 are disposed in a center region 10a and an outer peripheral region 10b surrounding the center region 10a on the insulated circuit substrate 10 using the solder 80, as illustrated in FIGS. 3A and 3B.

As illustrated in FIG. 3B, the insulated circuit substrate 10 having the sleeves 30 disposed thereon is illuminated from the side where the sleeves 30 are disposed, and is imaged by an imaging device 100, thereby capturing an image. Then, the binarization processing for the sleeves 30 is performed on the captured image to detect the center positions of the holes 31 of the sleeves 30.

With respect to the image acquisition using the imaging device 100, the sleeves 30 disposed in the center region 10a of the insulated circuit substrate 10 are imaged from directly above, whereas the sleeves 30 disposed in the outer peripheral region 10b of the insulated circuit substrate 10 are imaged in an oblique direction from an angle.

In addition, each sleeve 30 typically includes the cylindrical portion 32 with the hole 31 and the flanges 33 provided at both opening ends of the cylindrical portion 32. The end face of each flange 33 of the sleeve 30 has a recess formed to serve as a passage to discharge volatile component gas of flux and others produced during soldering between the flange 33 and the insulated circuit substrate 10, so that the flange 33 has an irregular surface. The flanges 33 at both opening ends in the sleeve 30 have an irregular end face. Therefore, in the image acquisition, shadows based on the irregularities of the end face of the flange 33 may appear depending on the position of the sleeve 30 on the insulated circuit substrate 10, i.e., an orientation from which the sleeve 30 is imaged.

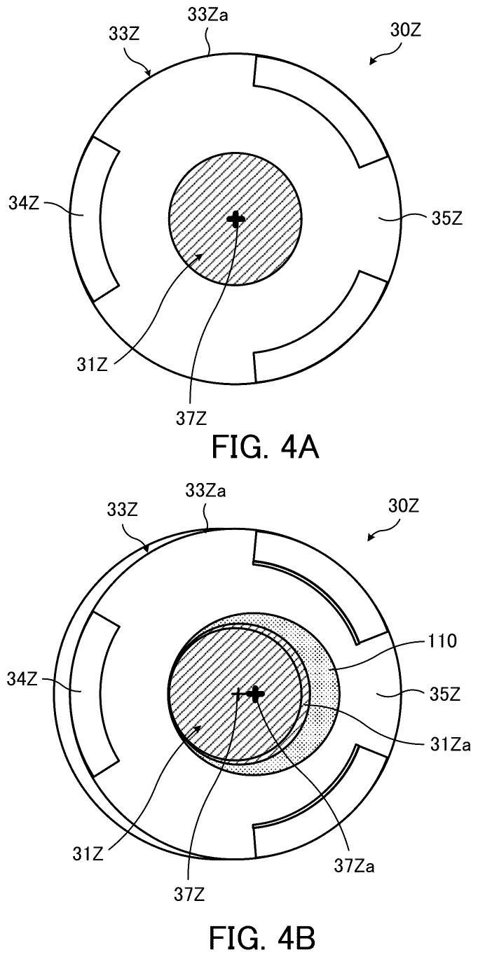

FIG. 4A is a main-part plan view schematically illustrating an example image of a sleeve 30 captured from directly above. FIG. 4B is a main-part plan view schematically illustrating an example image of the sleeve 30 captured from an angle.

FIGS. 4A and 4B each illustrate, as an example, a sleeve 30Z in which three protrusions 34Z are provided respectively at three positions along the outer periphery 33Za of each of the flanges 33Z provided at both opening ends of the cylindrical portion 32Z of the sleeve 30Z and a recess 35Z is provided in the region from around a hole 31Z to the outer periphery 33Za of the flange 33Z between adjacent protrusions 34Z. An irregular shape like the shape of this sleeve 30Z is described in U.S. Patent Application Publication No. 2009/0194884.

When the sleeve 30Z that has the flange 33Z with these protrusions 34Z and recess 35Z is imaged from directly above, the contour of the hole 31Z at the upper opening end (the image capturing side) overlaps the contour of the hole 31Z at the lower opening end (the soldering surface side), as illustrated in FIG. 4A. In addition, shadows of the protrusions 34Z do not appear on the end face of the flange 33Z on the image capturing side. Therefore, imaging the sleeve 30Z from directly above minimizes the effects of the shadows created by the irregularities (hole 31Z, recess 35Z, or protrusions 34Z) of the flange 33Z, which enables accurate image recognition of the contour of the hole 31Z through the binarization processing. Then, a circle is set on the contour of the hole 31Z, and the center of the circle is detected as the center 37Z of the hole 31Z. As a result, the actual position of the center 37Z of the hole 312 is detected with high accuracy.

When the sleeve 30Z that has the flange 33Z with these protrusions 34Z and recess 35Z is imaged from an angle, on the other hand, the inner wall surface 31Za of the hole 31Z appears within the hole 31Z at the upper opening end (the image capturing side), and a shadow 110 (partially illustrated for convenience) appears due to the irregularities (hole 31Z, recess 35Z, or protrusions 34Z) on the flange 33Z, as illustrated in FIG. 4B. In this connection, FIG. 4B illustrates an example in which the sleeve 30Z is illuminated from the left side of the drawing and is imaged by the imaging device 100 (FIG. 3B).

In the flange 33Z of the sleeve 30Z, the circumference of the hole 31Z is entirely surrounded by the recess 35Z. Therefore, when the sleeve 30Z is imaged from an angle, the shadow 110 created by the irregularities of the flange 33Z may extend onto the recess 35Z. In this case, the boundary between the hole 31Z or its inner wall surface 31Za and the recess 35Z of the flange 33Z surrounding it may become ambiguous over a relatively long region along the edge of the hole 312. This may result in poor image recognition in which a region recognized as the hole 31Z through the binarization processing is different from the actual region of the hole 31Z. In other words, the region of the hole 31Z and the region of the shadow 110 appearing on the recess 35Z outside the region of the hole 31Z may erroneously be recognized as the hole 31Z of the sleeve 30Z. For this reason, when the sleeve 30Z is imaged from an angle, a deviation may occur in the contour of the hole 31Z recognized through the binarization processing of the image. If a circle is set on the deviated contour of the hole 31Z (including the hole 31Z and the shadow 110 appearing outside the hole 312) and then the center of the circle is detected as the center 37Za of the hole 31Z, the position of the detected center is deviated from the actual position of the center 37Z. As described above, when the sleeve 30Z is imaged from an angle, the actual position of the center 37Z of the hole 31Z may fail to be detected with high accuracy.

In the case where this sleeve 30Z is used as each sleeve 30 of the semiconductor device 1 illustrated in FIG. 2, the sleeves 30Z disposed in the outer peripheral region 10b out of the center region 10a and outer peripheral region 10b of the insulated circuit substrate 10 are more likely to be imaged from an angle as illustrated in FIG. 4B. Therefore, the sleeves 30Z disposed in the outer peripheral region 10b of the insulated circuit substrate 10 are more likely to cause a deviation from the actual position of the center 37Z of the hole 312 than the sleeves 30Z disposed in the center region 10a.

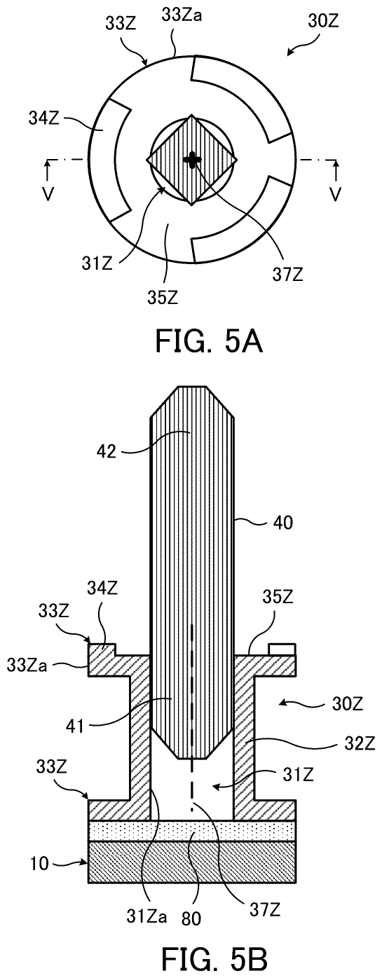

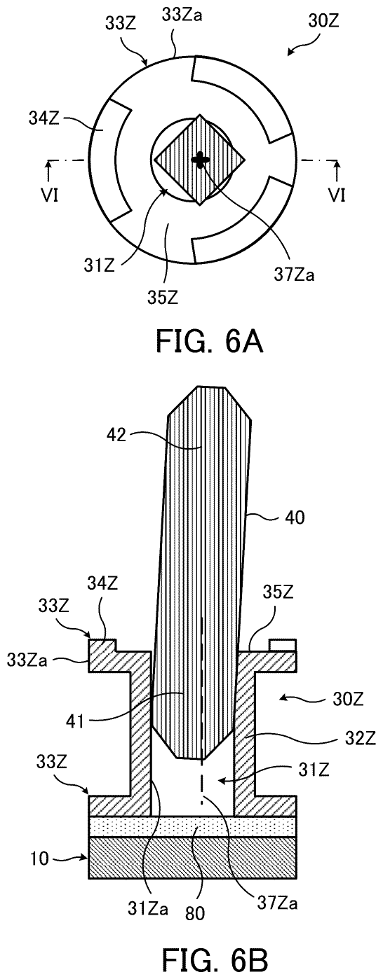

External terminals 40 are inserted into the centers 37Z and 37Za of the holes 31Z detected through the image acquisition and binarization processing as described above, with the automatic insertion machine. FIGS. 5A to 6B illustrate examples of a state in which an external terminal 40 is inserted.

FIG. 5A is a main-part plan view schematically illustrating an example state in which an external terminal 40 is inserted into the center 37Z of a hole 31Z detected with respect to the sleeve 30Z imaged from directly above. FIG. 5B is a main-part sectional view schematically illustrating the example state in which the external terminal 40 is inserted into the center 37Z of the hole 31Z detected with respect to the sleeve 30Z imaged from directly above. FIG. 5B is a sectional view taken along a line V-V of FIG. 5A. FIG. 6A is a main-part plan view schematically illustrating an example state in which an external terminal 40 is inserted into the center 37Za of a hole 31Z detected with respect to the sleeve 30Z imaged from an angle. FIG. 6B is a main-part sectional view schematically illustrating the example state in which the external terminal 40 is inserted into the center 37Za of the hole 31Z detected with respect to the sleeve 30Z imaged from the angle. FIG. 6B is a sectional view taken along a line VI-VI of FIG. 6A.

In the case where the sleeve 30Z is imaged from directly above, the actual position of the center 37Z of the hole 31Z is detected with high accuracy through image acquisition and binarization processing. The first end 41 of an external terminal 40 is inserted into the actual position of the center 37Z of the hole 312 with the automatic insertion machine. For example, a square bar-shaped external terminal 40 is pressure-inserted or fit into the hole 31Z while the outer periphery (corners) of the external terminal 40 deforms the inner wall surface 31Za of the hole 31Z. That is, in the case where the sleeve 30Z is imaged from directly above and the actual position of the center 37Z of the hole 312 is detected with high accuracy, the external terminal 40 is inserted in an upright position into the hole 31Z, as illustrated in FIGS. 5A and 5B.

In the case where the sleeve 30Z is imaged from an angle, on the other hand, the position of the center 37Za of the hole 31Z detected through the image acquisition and binarization processing is deviated from the actual position of the center 37Z. If the detected position of the center 37Za of the hole 31Z is deviated from the actual position, the first end 41 of an external terminal 40 is inserted into the position of the center 37Za of the hole 31Z deviated from the actual position with the automatic insertion machine. Therefore, for example, when a square bar-shaped external terminal 40 is pressure-inserted or fit into the hole 31Z while the outer periphery (corners) of the external terminal 40 deforms the inner wall surface 31Za of the hole 31Z, the outer periphery of the external terminal 40 exhibits uneven contact with and uneven pressing force to the inner wall surface 31Za of the hole 31Z. That is, in the case where the sleeve 30Z is imaged from the angle and the detected position of the center 37Za of the hole 31Z is deviated from the actual position, the external terminal 40 may be inserted in an inclined position into the hole 312, as illustrated in FIGS. 6A and 6B.

In the case where the sleeve 30Z as illustrated in FIGS. 4A to 6B is disposed as a sleeve 30 of the semiconductor device 1 (FIG. 2), the first end 41 of an external terminal 40 is inserted into the sleeve 30Z and the second end 42 of the external terminal 40 opposite to the first end 41 is drawn to the outside of the case 50. Then, for example, the second end 42 drawn to the outside of the case 50 is inserted into a connection hole of a circuit substrate having the connection hole so as to be connected to the circuit substrate. However, if the external terminal 40 is inserted in an inclined position into the sleeve 30Z as illustrated in FIGS. 6A and 6B, the second end 42 that is misaligned from its correct position collides with the circuit substrate, which may damage the external terminal 40 or the circuit substrate or may cause insertion failure in which the second end 42 of the external terminal 40 is not properly inserted into the connection hole of the circuit substrate.

In view of the foregoing, the techniques described in the following embodiments are provided to achieve a semiconductor device in which a deviation of the center position of a hole of a sleeve is minimized when the center position is detected through the binarization processing of an image of a flange of the sleeve and thus the inclination of an external terminal is minimized when one end of the external terminal is inserted into the sleeve.

### First Embodiment

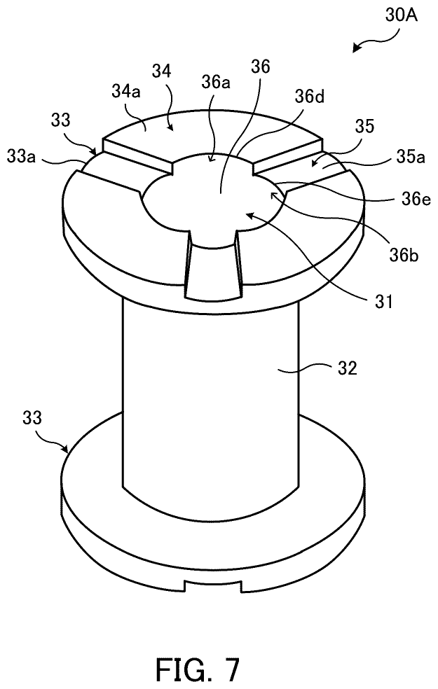

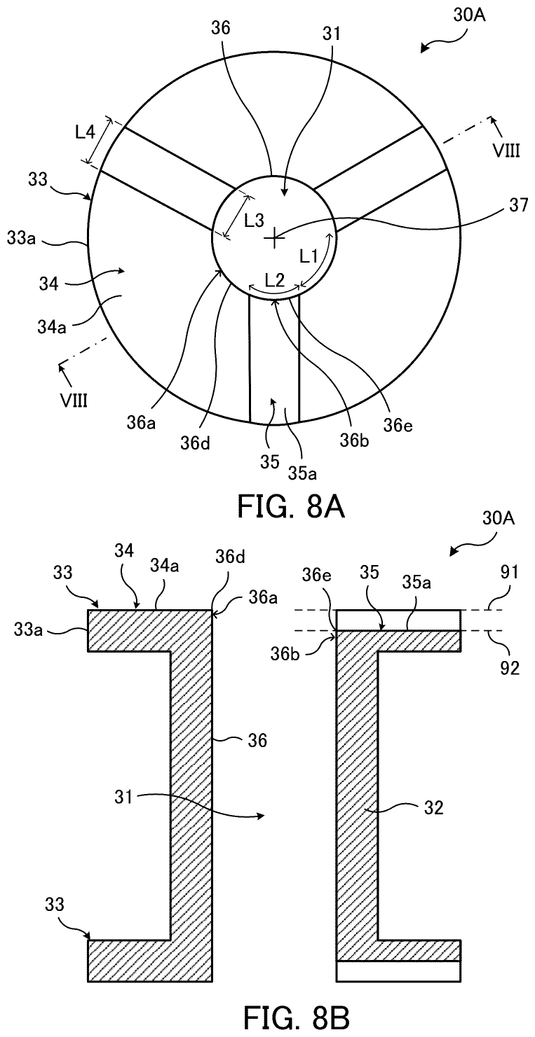

FIGS. 7 to 8B include views for describing an example sleeve according to a first embodiment. FIG. 7 is a main-part perspective view schematically illustrating the example sleeve. FIG. 8A is a main-part plan view schematically illustrating the example sleeve. FIG. 8B is a main-part sectional view schematically illustrating the example sleeve. FIG. 8B is a sectional view taken along a line VIII-VIII of FIG. 8A.

For example, a sleeve 30A as illustrated in FIGS. 7, 8A, and 8B is disposed as a sleeve 30 disposed on the insulated circuit substrate 10 of the semiconductor device 1 as illustrated in FIG. 2.

The sleeve 30A includes a cylindrical portion 32 with a hole 31 and flanges 33 provided at both opening ends of the cylindrical portion 32. Each flange 33 includes a plurality of protrusions 34 and a plurality of recesses 35 respectively provided between the plurality of protrusions 34. The protrusions 34 protrude in an axial direction of the cylindrical portion 32 away from the insulated circuit substrate 10 and extend in a radial direction of the cylindrical portion 32 from an opening edge of the hole 31 to an outer circumferential periphery of the flanges 33. The recesses 35 are recessed in the axial direction toward the insulated circuit substrate 10, and extend in the radial direction from the opening edge of the hole 31 to the outer circumferential periphery of the flange 33. The recesses 33 are provided respectively alternate with the protrusions 35 in a circumferential direction of the flanges 33. Here, a flange 33 with three protrusions 34 and three recesses 35 between the protrusions 34 is illustrated as an example. The flanges 33 provided at both opening ends of the cylindrical portion 32 have the same configuration. The plurality of protrusions 34 have the same shape, and the plurality of recesses 35 have the same shape.

In a plan view as seen from one opening end of the cylindrical portion 32, each protrusion 34 is provided in the flange 33 such as to extend from a first outer edge portion 36a in the inner surface 36 of the hole 31 to the outer periphery 33a of the flange 33. Each protrusion 34 has a top surface 34a that is continuous with the inner surface 36 in the first outer edge portion 36a so as to have a single flat surface parallel to the radial direction of the cylindrical portion 32. The top surface 34a is entirely flat in FIG. 7, but a portion of the top surface 34 at a side of an opening edge of the hole 31 may be excluded from the flat surface. In the sleeve 30A, the first outer edge portion 36a has a bent portion (also called “first bent portion”), where a right angle is formed by the inner surface 34 of the hole 31 and each of the top surfaces 34a in a cross section of the flange 33 including an axis of the cylindrical portion 32, that is continuous with the top surface 34a. The end 36d of the inner surface 36 in the first outer edge portion 36a is located in a first plane 91 (FIG. 8B) including the top surface 34a. In the plan view as seen from the one opening end of the cylindrical portion 32, the protrusions 34 are arranged to be rotationally symmetric with respect to the center 37 (FIG. 8A) of the hole 31 as an axis of symmetry. As an example, three protrusions 34 are arranged to be 120° rotationally symmetric with the center 37 of the hole 31 as the axis of symmetry.

In the plan view as seen from the one opening end of the cylindrical portion 32, each recess 35 is provided in the flange 33 such as to extend from a second outer edge portion 36b in the inner surface 36 of the hole 31 to the outer periphery 33a of the flange 33. Each recess 35 has a bottom surface 35a that is continuous with the inner surface 36 in the second outer edge portion 36b so as to have a single flat surface parallel to the radial direction. The bottom surface 35a is entirely flat in FIG. 7, but a portion of the bottom surface 35a at a side of an opening edge of the hole 31 may be excluded from the flat surface. In the sleeve 30A, the second outer edge portion 36b has a bent portion (also called “second bent portion”), where a right angle is formed by the inner surface 34 of the hole 31 and each of the bottom surface 35a in a cross section of the flange 33 including an axis of the cylindrical portion 32, that is continuous with the bottom surface 35a. The end 36e of the inner surface 36 in the second outer edge portion 36b is located in a second plane 92 including the bottom surface 35a (FIG. 8B). In the plan view as seen from the one opening end of the cylindrical portion 32, the recesses 35 are arranged to be rotationally symmetric with respect to the center 37 of the hole 31 as an axis of symmetry (FIG. 8A). As an example, three recesses 35 are arranged to be 120° rotationally symmetric with the center 37 of the hole 31 as the axis of symmetry. For example, each recess 35 is provided such that the depth measured from the top surface 34a of a protrusion 34 to the bottom surface 35a of the recess 35 is 0.055 mm or less.

For example, in the plan view as seen from the one opening end of the cylindrical portion 32, the protrusions 34 and recesses 35 are provided in the flange 33 such that the sum of the lengths L1 (FIG. 8A) of the first outer edge portions 36a is greater than or equal to the sum of the lengths L2 (FIG. 8A) of the second outer edge portions 36b. Here, the length L1 of a first outer edge portion 36a is also considered as the length of a transition area from the first outer edge portion 36a to the top surface 34a of a protrusion 34, or the length of the area of the end 36d of the inner surface 36 in the first outer edge portion 36a. The length L2 of a second outer edge portion 36b is also considered as the length of a transition area from the second outer edge portion 36b to the bottom surface 35a of a recess 35, or the length of the area of the end 36e of the inner surface 36 in the second outer edge portion 36b. In other word, each of the top surfaces of the plurality of protrusions has an inner circumferential periphery at the opening edge of the hole 31. The inner circumferential periphery has an arc shape with a predetermined radius. In that case, a sum of a length of the inner circumferential periphery of each of the top surfaces 34a is greater than 50% of a circumference of a circle with the predetermined radius, since the sum of lengths L1 is greater than the sum of lengths L2.

For example, in the plan view as seen from the one opening end of the cylindrical portion 32, each recess 35 is provided in the flange 33 such that the length L3 (FIG. 8A) of a straight line connecting both ends of the recess 35 in the second outer edge portion 36b that is continuous with the bottom surface 35a of the recess 35 is equal to the length L4 (FIG. 8A) of a straight line connecting both ends of the recess 35 in the outer periphery 33a of the flange 33. That is, each recess 35 extends from the second outer edge portion 36b in the inner surface 36 of the hole 31 to the outer periphery 33a of the flange 33, with a constant width. The length L3 can also be defined as a length of a line passing through two points at which two side edges of the bottom surface 35a of each of the recesses 35 extend from the opening edge of the through hole 31 to the outer circumferential periphery of the flange 33 respectively intersect the opening edge of the through hole 31. The length L4 can also be defined as a length of a line passing through two points at which the two side edges of the bottom surface 35a respectively intersect the outer circumferential periphery of the flange 33.

As the sleeves 30 of the semiconductor device 1 as illustrated in FIG. 2, sleeves 30A each provided with flanges 33 as illustrated in FIGS. 7, 8A, and 8B are arranged in both the center region 10a and the outer peripheral region 10b of the insulated circuit substrate 10 or in at least the outer peripheral region 10b out of the center region 10a and outer peripheral region 10b. In each sleeve 30A, one of the flanges 33 at both opening ends thereof is bonded to a conductive layer 12, 13, or 14 of the insulated circuit substrate 10 using a solder 80, as described earlier.

The solder 80 used to bond the sleeves 30A contains a volatile material such as flux. During the bonding of a sleeve 30A, the melting of the solder 80 causes volatilization of the flux and others in the solder 80, thereby producing gas. Here, each flange 33 of the sleeve 30A bonded using the solder 80 is provided with the recesses 35 each extending from the hole 31 (second outer edge portion 36b in the inner surface 36) to the outer periphery 33a. Therefore, the gas of flux and others produced from the solder 80 during the bonding is exhausted to the outside of the flange 33 through the recesses 35, as well as through the hole 31 of the sleeve 30A. If only the hole 31 is a passage to exhaust the gas of flux and others, the gas pressure excessively increases, and the molten solder 80 is scattered together with the exhausted gas and adheres to the inner surface 36 of the hole 31, which may block the insertion of an external terminal 40 into the hole 31 later. By contrast, in the sleeve 30A, the gas of flux and others is exhausted to the outside of the flange 33 through the recesses 35 provided in the flange 33, which effectively prevents the excessive increase in the gas pressure and the scattering of the solder 80 caused by the excessive increase in the gas pressure.

In addition, in each flange 33 of the sleeve 30A, the protrusions 34 that sandwich the recesses 35 are provided to extend from the hole 31 (first outer edge portion 36a in the inner surface 36) to the outer periphery 33a and are arranged to be rotationally symmetric with respect to the center 37 of the hole 31 as an axis of symmetry. This stabilizes the posture of the sleeve 30A at the time of bonding the flange 33 using the solder 80 and thus prevents the sleeve 30A from being connected in an inclined position to the insulated circuit substrate 10.

In the case where the sleeve 30A as illustrated in FIGS. 7, 8A, and 8B is arranged as a sleeve 30 of the semiconductor device 1 as illustrated in FIG. 2, an external terminal 40 is connected to the sleeve 30A bonded to the insulated circuit substrate 10 as illustrated in FIG. 2. More specifically, the first end 41 of the external terminal 40 is inserted into the hole 31 of the sleeve 30A.

In connecting the external terminal 40, prior to the insertion of the first end 41 thereof, an image of the sleeve 30A is captured from the side where the flange 33 opposite to the flange 33 bonded to the insulated circuit substrate 10 using the solder 80 as described above is located, and then the binarization processing is performed on the image to detect the center 37 of the hole 31 of the sleeve 30A.

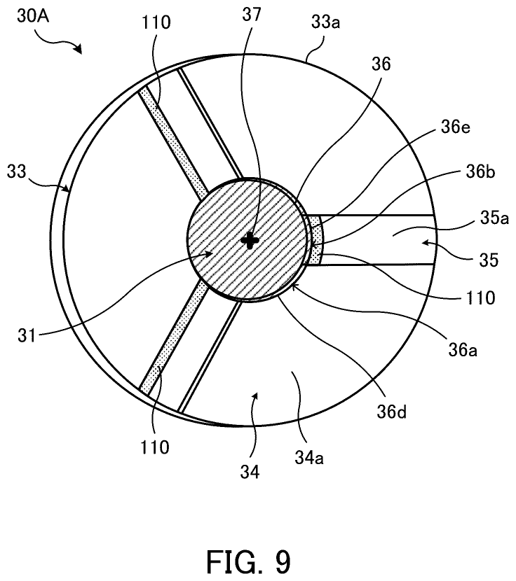

Each flange 33 of the sleeve 30A is provided with the protrusions 34 extending from the first outer edge portions 36a in the inner surface 36 of the hole 31 to the outer periphery 33a of the flange 33. In addition, each flange 33 is provided with the recesses 35 extending from the second outer edge portions 36b in the inner surface 36 of the hole 31 to the outer periphery 33a of the flange 33. In other words, the top surfaces 34a of the protrusions 34 extend to the first outer edge portions 36a of the hole 31, and the bottom surfaces 35a of the recesses 35 extend to the second outer edge portion 36b of the hole 31. This reduces the effects of shadows appearing on the flange 33 when an image of the flange 33 of the sleeve 30A is captured. Then, through the binarization processing, it is possible to achieve highly accurate image recognition of the first outer edge portions 36a that are continuous with the top surfaces 34a of the protrusions 34, which are less affected by shadows, out of the first outer edge portions 36a (bent portions) and second outer edge portions 36b (bent portions) of the hole 31 of the sleeve 30A. This feature will be described with reference to FIG. 9.

FIG. 9 is a view for describing an example state of a sleeve being imaged according to the first embodiment. FIG. 9 is a main-part plan view schematically illustrating an example image of a sleeve captured from an angle.

When an image of the sleeve 30A is captured from an angle, shadows 110 appear due to the irregularities (hole 31, recesses 35, and protrusions 34) of the flange 33 on the flange 33 of the sleeve 30A, as illustrated in FIG. 9. In this connection, FIG. 9 illustrates an example in which the sleeve 30A is illuminated from the left side of the drawing and is imaged by the imaging device 100 (FIG. 3B).

When the sleeve 30A is imaged from an angle, the shadows 110 appear on the bottom surfaces 35a of the recesses 35 but the shadows 110 are unlikely to appear on the top surfaces 34a of the protrusions 34, as illustrated in FIG. 9. In the sleeve 30A, the top surfaces 34a of the protrusions 34 on which the shadows 110 are unlikely to appear respectively extend to the first outer edge portions 36a of the hole 31. In image recognition through the binarization processing, the hole 31 is recognized as a black region, and the top surfaces 34a of the protrusions 34 on which the shadows 110 are unlikely to appear are recognized as white regions. That is, the ambiguity of the boundaries between the first outer edge portions 36a of the hole 31 and the top surfaces 34a of the protrusions 34 due to the effects of the shadows 110 or the ambiguity of the edge of the hole 31 over a relatively long region due to the effects of the shadows 110 is mitigated.

It is therefore possible to achieve highly accurate image recognition to detect the positions of the first outer edge portions 36a of the hole 31 and subsequently detect the contour of the hole 31 on the basis of the information on the positions of the first outer edge portions 36a. The image recognition accuracy of the first outer edge portions 36a and the image recognition accuracy of the contour of the hole 31 to be detected thereafter are improved by setting the sum of the lengths L1 of the first outer edge portions 36a to greater than or equal to the sum of the lengths L2 of the second outer edge portions 36b. The highly accurate image recognition of the contour of the hole 31 allows for precise detection of the position of the center 37 of the hole 31 with minimizing a deviation from its actual position.

Conventionally, a deviation from the actual position of the center 37 of a hole 31 tends to occur in the sleeves 30 disposed in the outer peripheral region 10b, which are more likely to be affected by shadows in a captured image, among the sleeves 30 disposed in the center region 10a and outer peripheral region 10b of the insulated circuit substrate 10. To deal with this, the sleeve 30A with the flanges 33 each having the protrusions 34 and recesses 35 as described above is arranged in at least the outer peripheral region 10b of the insulated circuit substrate 10, which allows for precise detection of the position of the center 37 of the hole 31 with minimizing a deviation.

As illustrated in FIG. 2, an external terminal 40 is inserted into the position of the center 37 of the hole 31 detected as described above, with the automatic insertion machine. Since the first end 41 of the external terminal 40 is inserted into the hole 31 whose center 37 has been detected with high accuracy, the external terminal 40 is effectively prevented from being inclined with respect to the sleeve 30A. The prevention of the inclination of the external terminal 40 results in reducing the possibility of damage, insertion failure, or another due to a collision of the second end 42 of the external terminal 40 when the second end 42 is inserted in a circuit substrate or the like.

### Second Embodiment

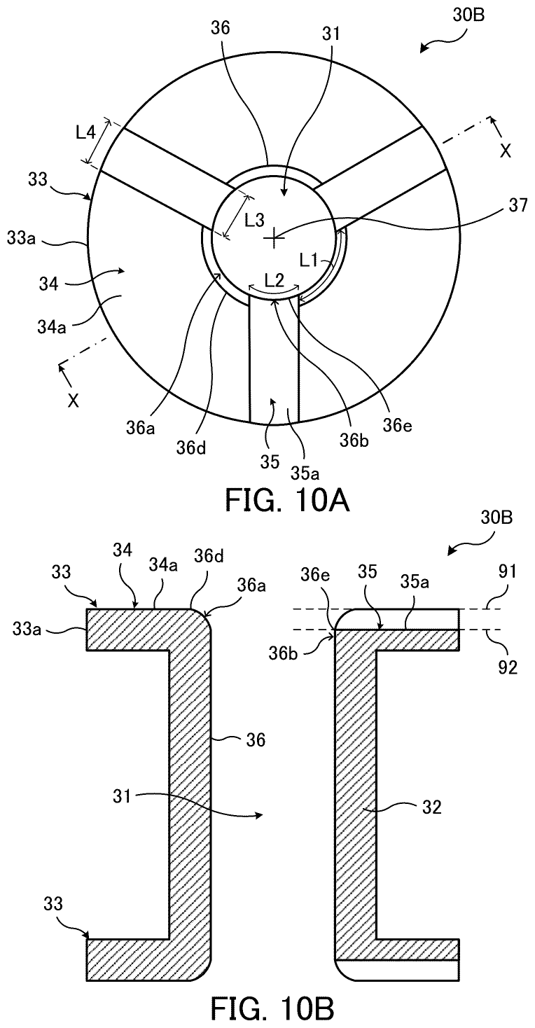

FIGS. 10A and 10B are views for describing an example sleeve according to a second embodiment. FIG. 10A is a main-part plan view schematically illustrating the example sleeve. FIG. 10B is a main-part sectional view schematically illustrating the example sleeve. FIG. 10B is a sectional view taken along a line X-X of FIG. 10A.

For example, a sleeve 30B as illustrated in FIGS. 10A and 10B is disposed as a sleeve 30 disposed on the insulated circuit substrate 10 in the semiconductor device 1 as illustrated in FIG. 2.

The sleeve 30B is configured to have a flange 33 with a plurality (three as an example) of protrusions 34 and a plurality (three as an example) of recesses 35 at each of both opening ends of a cylindrical portion 32 The flanges 33 at both opening ends have the thereof. same configuration. The plurality of protrusions 34 have the same shape, and the plurality of recesses 35 have the same shape.

In a plan view as seen from one opening end of the cylindrical portion 32, each protrusion 34 is provided in the flange 33 such as to extend from a first outer edge portion 36a in the inner surface 36 of a hole 31 to the outer periphery 33a of the flange 33. Each protrusion 34 has a top surface 34a that is continuous with the inner surface 36 in the first outer edge portion 36a. In the sleeve 30B, the first outer edge portion 36a has a curved portion (also called “first curved portion”), where the top surfaces 34a at an opening edge side of the hole 31 are rounded in a cross section of the flange 33 including an axis of the cylindrical portion 32, that is continuous with the top surface 34a. The end 36d of the inner surface 36 in the first outer edge portion 36a is located in a first plane 91 (FIG. 10B) including the top surface 34a. In the plan view as seen from the one opening end of the cylindrical portion 32, the protrusions 34 are arranged to be rotationally symmetric with respect to the center 37 (FIG. 10A) of the hole 31 as an axis of symmetry. As an example, three protrusions 34 are arranged to be 120° rotationally symmetric with the center 37 of the hole 31 as the axis of symmetry.

In the plan view as seen from the one opening end of the cylindrical portion 32, each recess 35 is provided in the flange 33 such as to extend from a second outer edge portion 36b in the inner surface 36 of the hole 31 to the outer periphery 33a of the flange 33. Each recess 35 has a bottom surface 35a that is continuous with the inner surface 36 in the second outer edge portion 36b. In the sleeve 30B, the second outer edge portion 36b has a bent portion (also called “second bent portion”), where the bottom surface 35a at an opening edge side of the hole 31 are rounded in a cross section of the flange 33 including an axis of the cylindrical portion 32, that is continuous with the bottom surface 35a. The end 36e of the inner surface 36 in the second outer edge portion 36b is located in a second plane 92 (FIG. 10B) including the bottom surface 35a. In the plan view as seen from the one opening end of the cylindrical portion 32, the recesses 35 are arranged to be rotationally symmetric with respect to the center 37 (FIG. 10A) of the hole 31 as an axis of symmetry. As an example, three recesses 35 are arranged to be 120° rotationally symmetric with the center 37 of the hole 31 as the axis of symmetry. Each recess 35 is provided such that the depth measured from the top surface 34a of a protrusion 34 to the bottom surface 35a of the recess 35 is 0.055 mm or less, for example.

In addition, in the sleeve 30B, for example, in the plan view as seen from the one opening end of the cylindrical portion 32, the protrusions 34 and recesses 35 are provided in the flange 33 such that the sum of the lengths L1 (FIG. 10A) of the first outer edge portions 36a is greater than or equal to the sum of the lengths L2 (FIG. 10A) of the second outer edge portions 36b.

In the sleeve 30B, for example, in the plan view as seen from the one opening end of the cylindrical portion 32, each recess 35 is provided in the flange 33 such that the length L3 (FIG. 10A) of a straight line connecting both ends of the recess 35 in the second outer edge portion 36b that is continuous with the bottom surface 35a of the recess 35 is equal to the length L4 (FIG. 10A) of a straight line connecting both ends of the recess 35 in the outer periphery 33a of the flange 33. That is, each recess 35 extends from the second outer edge portion 36b in the inner surface 36 of the hole 31 to the outer periphery 33a of the flange 33, with a constant width.

In the sleeve 30B, the first outer edge portions 36a in the inner surface 36 of the hole 31 are configured to have a curved portion. Having this configuration, the sleeve 30B differs from the sleeve 30A described earlier in the first embodiment. The flat top surface 34a of each protrusion 34, which is continuous from the end 36d of a first outer edge portion 36a having the curved portion, extends to the outer periphery 33a. The curved portions of the first outer edge portions 36a may be unavoidably formed during the manufacturing of the sleeve 30B or may be formed by grinding or pressing bent portions (see FIG. 8B). On the other hand, the second outer edge portions 36b in the inner surface 36 of the hole 31 are configured to have a bent portion, as in the sleeve 30A described earlier in the first embodiment. The flat bottom surface 35a of each recess 35, which is continuous from the end 36e of a second outer edge portion 36b having the bent portion, extends to the outer periphery 33a.

The sleeve 30B configured as above provides the same effects as the sleeve 30A described earlier in the first embodiment. More specifically, since the flange 33 is provided with the recesses 35 each extending from the hole 31 to the outer periphery 33a, gas generated during the soldering of the sleeve 30B is exhausted to the outside of the flange 33 through the recesses 35, which effectively prevents the scattering of the solder 80 caused by an increase in gas pressure. Since the protrusions 34 each extending from the hole 31 to the outer periphery 33a are arranged to be rotationally symmetric with respect to the center 37 of the hole 31 as an axis of symmetry, the posture of the sleeve 30B is stabilized during the soldering, and thus the sleeve 30B is prevented from being inclined.

Further, in the sleeve 30B, the first outer edge portions 36a that are continuous with the protrusions 34 are configured to have a curved portion. As compared with the case where the first outer edge portions 36a have a bent portion, the space between the flange 33 and a conductive layer (conductive layer 12, conductive layer 13, or conductive layer 14) of the insulated circuit substrate 10 expands, which increases an amount of solder 80 between the flange 33 and the conductive layer of the insulated circuit substrate 10 and thus enhances the bonding strength. Also, since a space for placing the solder 80 is ensured between each curved portion of the flange 33 of the sleeve 30B and the conductive layer of the insulated circuit substrate 10, the solder 80 remains in that space, which reduces an amount of solder 80 going into the hole 31 and an amount of solder 80 crawling up the inner surface 36.

In addition, in the sleeve 30B, the protrusions 34 and recesses 35 each extend from the hole 31 to the outer periphery 33a of the flange 33. In other words, the top surfaces 34a of the protrusions 34 extend to the first outer edge portions 36a of the hole 31, and the bottom surfaces 35a of the recesses 35 extend to the second outer edge portions 36b of the hole 31. Therefore, in detecting the position of the center 37 of the hole 31 prior to the insertion of an external terminal 40, the first outer edge portions 36a that are continuous with the top surfaces 34a of the protrusions 34, which are less affected by shadows, out of the first outer edge portions 36a (curved portions) and second outer edge portions 36b (bent portions) of the hole 31 are recognized with high accuracy through the binarization processing of an image of the flange 33. That is, the ambiguity of the boundaries between the first outer edge portions 36a of the hole 31 and the top surfaces 34a of the protrusions 34 due to the effects of shadows is mitigated. This achieves highly accurate image recognition to detect the positions of the first outer edge portions 36a of the hole 31 and subsequently detect the contour of the hole 31 on the basis of the information on the positions of the first outer edge portions 36a. The image recognition accuracy of the first outer edge portions 36a and the image recognition accuracy of the contour of the hole 31 to be detected thereafter are improved by setting the sum of the lengths L1 of the first outer edge portions 36a to greater than or equal to the sum of the lengths L2 of the second outer edge portions 36b.

The highly accurate image recognition of the contour of the hole 31 allows for precise detection of the position of the center 37 of the hole 31 with minimizing a deviation from its actual position. In inserting the first end 41 of an external terminal 40 into the detected position of the center 37 with the automatic insertion machine, the external terminal 40 is prevented from being inclined. This results in reducing the possibility of damage, insertion failure, or another due to a collision of the second end 42 of the external terminal 40 when the second end 42 is inserted in a circuit substrate or the like.

### Third Embodiment

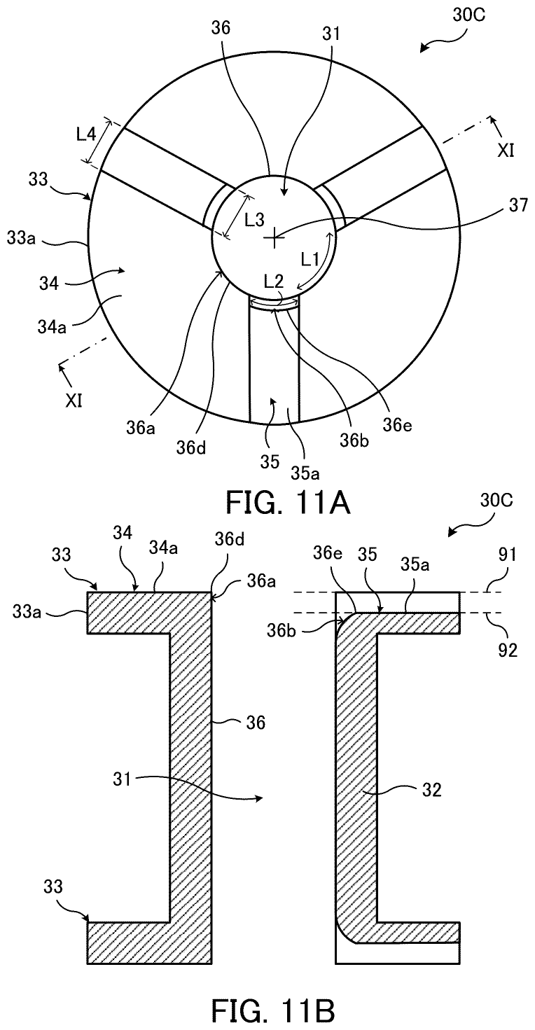

FIGS. 11A and 11B are views for describing an example sleeve according to a third embodiment. FIG. 11A is a main-part plan view schematically illustrating the example sleeve. FIG. 11B is a main-part sectional view schematically illustrating the example sleeve. FIG. 11B is a sectional view taken along a line XI-XI of FIG. 11A.

For example, a sleeve 30C as illustrated in FIGS. 11A and 11B is disposed as a sleeve 30 disposed on the insulated circuit substrate 10 in the semiconductor device 1 as illustrated in FIG. 2.

The sleeve 30C is configured to have a flange 33 with a plurality (three as an example) of protrusions 34 and a plurality (three as an example) of recesses 35 at each of both opening ends of a cylindrical portion 32 thereof. The flanges 33 at both opening ends have the same configuration. The plurality of protrusions 34 have the same shape, and the plurality of recesses 35 have the same shape.

In a plan view as seen from one opening end of the cylindrical portion 32, each protrusion 34 is provided in the flange 33 such as to extend from a first outer edge portion 36a in the inner surface 36 of a hole 31 to the outer periphery 33a of the flange 33. Each protrusion 34 has a top surface 34a that is continuous with the inner surface 36 in the first outer edge portion 36a. In the sleeve 30C, the first outer edge portion 36a has a bent portion (also called “first bent portion”) that is continuous with the top surface 34a. The end 36d of the inner surface 36 in the first outer edge portion 36a is located in a first plane 91 (FIG. 11B) including the top surface 34a. In the plan view as seen from the one opening end of the cylindrical portion 32, the protrusions 34 are arranged to be rotationally symmetric with respect to the center 37 (FIG. 11A) of the hole 31 as an axis of symmetry. As an example, three protrusions 34 are arranged to be 120° rotationally symmetric with the center 37 of the hole 31 as the axis of symmetry.

In the plan view as seen from the one opening end of the cylindrical portion 32, each recess 35 is provided in the flange 33 such as to extend from a second outer edge portion 36b in the inner surface 36 of the hole 31 to the outer periphery 33a of the flange 33. Each recess 35 has a bottom surface 35a that is continuous with the inner surface 36 in the second outer edge portion 36b. In the sleeve 30C, the second outer edge portion 36b has a curved portion (also called “second curved portion”) that is continuous with the bottom surface 35a. The end 36e of the inner surface 36 in the second outer edge portion 36b is located in a second plane 92 (FIG. 11B) including the bottom surface 35a. In the plan view as seen from the one opening end of the cylindrical portion 32, the recesses 35 are arranged to be rotationally symmetric with respect to the center 37 (FIG. 11A) of the hole 31 as an axis of symmetry. As an example, three recesses 35 are arranged to be 120° rotationally symmetric with the center 37 of the hole 31 as the axis of symmetry. Each recess 35 is provided such that the depth measured from the top surface 34a of a protrusion 34 to the bottom surface 35a of the recess 35 is 0.055 mm or less.

In addition, in the sleeve 30C, for example, in the plan view as seen from the one opening end of the cylindrical portion 32, the protrusions 34 and recesses 35 are provided in the flange 33 such that the sum of the lengths L1 (FIG. 11A) of the first outer edge portions 36a is greater than or equal to the sum of the lengths L2 (FIG. 11A) of the second outer edge portions 36b.

For example, in the sleeve 30C, in the plan view as seen from the one opening end of the cylindrical portion 32, each recess 35 is provided in the flange 33 such that the length L3 (FIG. 11A) of a straight line connecting both ends of the recess 35 in the second outer edge portion 36b that is continuous with the bottom surface 35a of the recess 35 is equal to the length L4 (FIG. 11A) of a straight line connecting both ends of the recess 35 in the outer periphery 33a of the flange 33. That is, each recess 35 extends from the second outer edge portion 36b in the inner surface 36 of the hole 31 to the outer periphery 33a of the flange 33, with a constant width.

In the sleeve 30C, the second outer edge portions 36b in the inner surface 36 of the hole 31 are configured to have a curved portion. Having this configuration, the sleeve 30C differs from the sleeve 30A described earlier in the first embodiment. The flat bottom surface 35a of each recess 35, which is continuous from the end 36e of a second outer edge portion 36b having the curved portion, extends to the outer periphery 33a. The curved portions of the second outer edge portions 36b may be unavoidably formed during the manufacturing of the sleeve 30C or may be formed by grinding or pressing bent portions (see FIG. 8B). On the other hand, the first outer edge portions 36a in the inner surface 36 of the hole 31 are configured to have a bent portion, as in the sleeve 30A described earlier in the first embodiment. The flat top surface 34a of each protrusion 34, which is continuous from the end 36d of a first outer edge portion 36a having the bent portion, extends to the outer periphery 33a.

The sleeve 30C configured as above provides the same effects as the sleeve 30A described earlier in the first embodiment. More specifically, since the flange 33 is provided with the recesses 35 each extending from the hole 31 to the outer periphery 33a, gas generated during the soldering of the sleeve 30C is exhausted to the outside of the flange 33 through the recesses 35, which effectively prevents the scattering of the solder 80 caused by an increase in gas pressure. Since the protrusions 34 each extending from the hole 31 to the outer periphery 33a are arranged to be rotationally symmetric with respect to the center 37 of the hole 31 as the axis of symmetry, the posture of the sleeve 30C is stabilized during the soldering, and thus the sleeve 30C is prevented from being inclined.

Further, in the sleeve 30C, the second outer edge portions 36b that are continuous with the recesses 35 are configured to have a curved portion. As compared with the case where the second outer edge portions 36b have a bent portion, the space between the flange 33 and a conductive layer (conductive layer 12, conductive layer 13, or conductive layer 14) of the insulated circuit substrate 10 expands, which increases an amount of solder 80 between the flange 33 and the conductive layer of the insulated circuit substrate 10 and thus enhances the bonding strength. Also, since a space for placing the solder 80 is ensured between each curved portion of the flange 33 of the sleeve 30C and the conductive layer of the insulated circuit substrate 10, the solder 80 remains in that space, which reduces an amount of solder 80 going into the hole 31 and an amount of solder 80 crawling up the inner surface 36.

Still further, in the sleeve 30C, the protrusions 34 and recesses 35 each extend from the hole 31 to the outer periphery 33a of the flange 33. In other words, the top surfaces 34a of the protrusions 34 extend to the first outer edge portions 36a of the hole 31, and the bottom surfaces 35a of the recesses 35 extend to the second outer edge portions 36b of the hole 31. Therefore, in detecting the position of the center 37 of the hole 31 prior to the insertion of an external terminal 40, the first outer edge portions 36a that are continuous with the top surfaces 34a of the protrusions 34, which are less affected by shadows, out of the first outer edge portions 36a (bent portions) and second outer edge portions 36b (curved portions) of the hole 31 are recognized with high accuracy through the binarization processing of an image of the flange 33. That is, the ambiguity of the boundaries between the first outer edge portions 36a of the hole 31 and the top surfaces 34a of the protrusions 34 due to the effects of shadows is mitigated. This achieves highly accurate image recognition to detect the positions of the first outer edge portions 36a of the hole 31 and subsequently detect the contour of the hole 31 on the basis of the information on the positions of the first outer edge portions 36a. The image recognition accuracy of the first outer edge portions 36a and the image recognition accuracy of the contour of the hole 31 to be detected thereafter are improved by setting the sum of the lengths L1 of the first outer edge portions 36a to greater than or equal to the sum of the lengths L2 of the second outer edge portions 36b.

The highly accurate image recognition of the contour of the hole 31 allows for precise detection of the position of the center 37 of the hole 31 with minimizing a deviation from its actual position. In inserting the first end 41 of the external terminal 40 into the detected position of the center 37 with the automatic insertion machine, the external terminal 40 is prevented from being inclined. This results in reducing the possibility of damage, insertion failure, or another due to a collision of the second end 42 of the external terminal 40 when the second end 42 is inserted in a circuit substrate or the like.

In this connection, the above-described second embodiment exemplifies a configuration in which the first outer edge portions 36a in the inner surface 36 of the hole 31 that are continuous with the protrusions 34 have a curved portion and the second outer edge portions 36b in the inner surface 36 of the hole 31 that are continuous with the recesses 35 have a bent portion (FIGS. 10A and 10B). The above-described third embodiment, on the other hand, exemplifies a configuration in which the first outer edge portions 36a in the inner surface 36 of the hole 31 that are continuous with the protrusions 34 have a bent portion and the second outer edge portions 36b in the inner surface 36 of the hole 31 that are continuous with the recesses 35 have a curved portion (FIGS. 11A and 11B). Alternatively, the first outer edge portions 36a in the inner surface 36 of the hole 31 that are continuous with the protrusions 34 and the second outer edge portions 36b in the inner surface 36 of the hole 31 that are continuous with the recesses 35 may all be configured to have a curved portion. This configuration also provides the same effects as described earlier in both the second and third embodiments.

### Fourth Embodiment

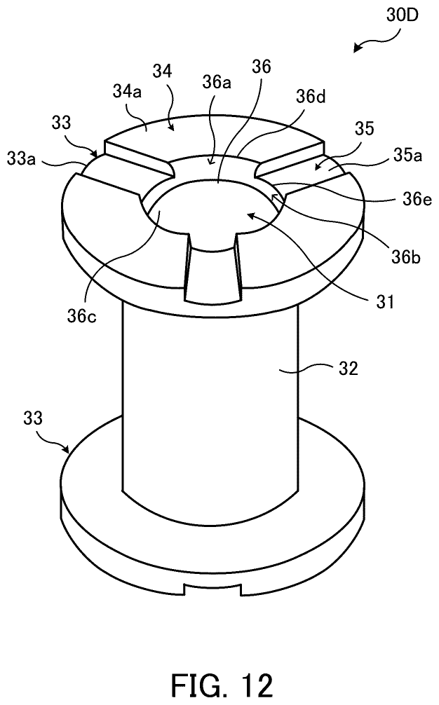

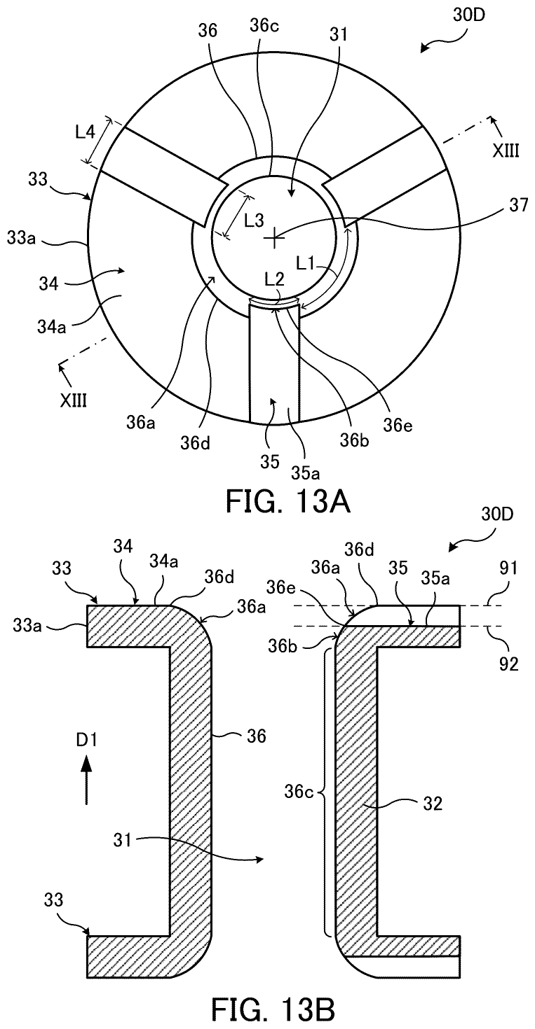

FIGS. 12 to 13B include views for describing an example sleeve according to a fourth embodiment. FIG. 12 is a main-part perspective view schematically illustrating the example sleeve. FIG. 13A is a main-part plan view schematically illustrating the example sleeve. FIG. 13B is a main-part sectional view schematically illustrating the example sleeve. FIG. 13B is a sectional view taken along a line XIII-XIII of FIG. 13A.

For example, a sleeve 30D as illustrated in FIGS. 12, 13A, and 13B is disposed as a sleeve 30 disposed on the insulated circuit substrate 10 in the semiconductor device 1 as illustrated in FIG. 2.

The sleeve 30D is configured to have a flange 33 with a plurality (three as an example) of protrusions 34 and a plurality (three as an example) of recesses 35 at each of both opening ends of a cylindrical portion 32 thereof. The flanges 33 at both opening ends have the same configuration. The plurality of protrusions 34 have the same shape, and the plurality of recesses 35 have the same shape.

In a plan view as seen from one opening end of the cylindrical portion 32, each protrusion 34 is provided in the flange 33 such as to extend from a first outer edge portion 36a in the inner surface 36 of a hole 31 to the outer periphery 33a of the flange 33. Each protrusion 34 has a top surface 34a that is continuous with the inner surface 36 in the first outer edge portion 36a. In the sleeve 30D, each first outer edge portion 36a has a curved portion (also called “first curved portion”) that is continuous with a top surface 34a. The end 36d of the inner surface 36 in the first outer edge portion 36a is located in a first plane 91 (FIG. 13B) including the top surface 34a. In the plan view as seen from the one opening end of the cylindrical portion 32, the protrusions 34 are arranged to be rotationally symmetric with respect to the center 37 (FIG. 13A) of the hole 31 as an axis of symmetry. As an example, three protrusions 34 are arranged to be 120° rotationally symmetric with the center 37 of the hole 31 as the axis of symmetry.

In the plan view as seen from the one opening end of the cylindrical portion 32, each recess 35 is provided in the flange 33 such as to extend from a second outer edge portion 36b in the inner surface 36 of the hole 31 to the outer periphery 33a of the flange 33. Each recess 35 has a bottom surface 35a that is continuous with the inner surface 36 in the second outer edge portion 36b. In the sleeve 30D, each second outer edge portion 36b has a curved portion (also called “second curved portion”) that is continuous with the bottom surface 35a. The end 36e of the inner surface 36 in the second outer edge portion 36b is located in a second plane 92 (FIG. 13B) including the bottom surface 35a. In the plan view as seen from the one opening end of the cylindrical portion 32, the recesses 35 are arranged to be rotationally symmetric with respect to the center 37 (FIG. 13A) of the hole 31 as an axis of symmetry. As an example, three recesses 35 are arranged to be 120° rotationally symmetric with the center 37 of the hole 31 as the axis of symmetry. Each recess 35 is provided such that the depth measured from the top surface 34a of a protrusion 34 to the bottom surface 35a of the recess 35 is 0.055 mm or less.

Here, in the sleeve 30D, the curved portions of the first outer edge portions 36a are formed by a curved surface that starts to curve at the end of an inner wall 36c linearly extending in the direction D1 in the inner surface 36 of the hole 31 and extends from the end to the top surfaces 34a of the protrusions 34. Each recess 35 is formed to have a depth such that the edge of the bottom surface 35a closest to the hole 31, i.e., the end 36e in the second outer edge portion 36b is located in the curved surface. All the curved portions of the first outer edge portions 36a and the curved portions of the second outer edge portions 36b are parts of the curved surface extending from the end of the inner wall 36c of the hole 31 to the top surfaces 34a and bottom surfaces 35a.

In addition, in the sleeve 30D, for example, in the plan view as seen from the one opening end of the cylindrical portion 32, the protrusions 34 and recesses 35 are provided in the flange 33 such that the sum of lengths L1 (FIG. 13A) of the first outer edge portions 36a is greater than or equal to the sum of the lengths L2 (FIG. 13A) of the second outer edge portions 36b.

In the sleeve 30D, for example, in the plan view as seen from the one opening end of the cylindrical portion 32, each recess 35 is provided in the flange 33 such that the length L3 (FIG. 13A) of a straight line connecting both ends of the recess 35 in the second outer edge portion 36b that is continuous with the bottom surface 35a of the recess 35 is equal to the length L4 (FIG. 13A) of a straight line connecting both ends of the recess 35 in the outer periphery 33a of the flange 33. That is, each recess 35 extends from the second outer edge portion 36b in the inner surface 36 of the hole 31 to the outer periphery 33a of the flange 33, with a constant width.

In the sleeve 30D, the first outer edge portions 36a and second outer edge portions 36b in the inner surface 36 of the hole 31 are configured to have a curved portion. Having this configuration, the sleeve 30D differs from the sleeve 30A described earlier in the first embodiment. The flat top surface 34a of each protrusion 34, which is continuous from the end 36d of a first outer edge portion 36a having the curved portion, extends to the outer periphery 33a. The flat bottom surface 35a of each recess 35, which is continuous from the end 36e of a second outer edge portion 36b having the curved portion, extends to the outer periphery 33a. The curved portions of the first outer edge portions 36a and second outer edge portions 36b may be unavoidably formed during the manufacturing of the sleeve 30D or may be formed by grinding or pressing bent portions (see FIG. 8B).

The sleeve 30D configured as above provides the same effects as the sleeve 30A described earlier in the first embodiment. More specifically, since the flange 33 is provided with the recesses 35 each extending from the hole 31 to the outer periphery 33a, gas generated during the soldering of the sleeve 30D is exhausted to the outside of the flange 33 through the recesses 35, which effectively prevents the scattering of the solder 80 caused by an increase in gas pressure. Since the protrusions 34 each extending from the hole 31 to the outer periphery 33a are arranged to be rotationally symmetric with respect to the center 37 of the hole 31 as the axis of symmetry, the posture of the sleeve 30D is stabilized during the soldering, and thus the sleeve 30D is prevented from being inclined.

Further, in the sleeve 30D, the first outer edge portions 36a that are continuous with the protrusions 34 and the second outer edge portions 36b that are continuous with the recesses 35 are configured to have a curved portion. As compared with the case where the first outer edge portions 36a and second outer edge portions 36b have a bent portion, the space between the flange 33 and a conductive layer (conductive layer 12, conductive layer 13, or conductive layer 14) of the insulated circuit substrate 10 expands, which increases an amount of solder 80 between the flange 33 and the conductive layer of the insulated circuit substrate 10 and thus enhances the bonding strength. Also, a space for placing the solder 80 is ensured between each curved portion of the flange 33 of the sleeve 30D and the conductive layer of the insulated circuit substrate 10, the solder 80 remains in that space, which reduces an amount of solder 80 going into the hole 31 and an amount of solder 80 crawling up the inner surface 36.

In the sleeve 30D, the protrusions 34 and recesses 35 each extend from the hole 31 to the outer periphery 33a of the flange 33. In other words, the top surfaces 34a of the protrusions 34 extend to the first outer edge portions 36a of the hole 31, and the bottom surfaces 35a of the recesses 35 extend to the second outer edge portions 36b of the hole 31. Therefore, in detecting the position of the center 37 of the hole 31 prior to the insertion of an external terminal 40, the first outer edge portions 36a that are continuous with the top surfaces 34a of the protrusions 34, which are less affected by shadows, out of the first outer edge portions 36a (curved portions) and second outer edge portions 36b (curved portions) of the hole 31 are recognized with high accuracy through the binarization processing of an image of the flange 33. That is, the ambiguity of the boundaries between the first outer edge portions 36a of the hole 31 and the top surfaces 34a of the protrusions 34 due to the effects of shadows is mitigated. This achieves highly accurate image recognition to detect the positions of the first outer edge portions 36a of the hole 31 and subsequently detect the contour of the hole 31 on the basis of the information on the positions of the first outer edge portions 36a. The image recognition accuracy of the first outer edge portions 36a and the image recognition accuracy of the contour of the hole 31 to be detected thereafter are improved by setting the sum of the lengths L1 of the first outer edge portions 36a to greater than or equal to the sum of the lengths L2 of the second outer edge portions 36b.

The highly accurate image recognition of the contour of the hole 31 allows for precise detection of the position of the center 37 of the hole 31 with minimizing a deviation from its actual position. In inserting the first end 41 of the external terminal 40 into the detected position of the center 37 with the automatic insertion machine, the external terminal 40 is prevented from being inclined. This results in reducing the possibility of damage, insertion failure, or another due to a collision of the second end 42 of the external terminal 40 when the second end 42 is inserted in a circuit substrate or the like.

### Fifth Embodiment

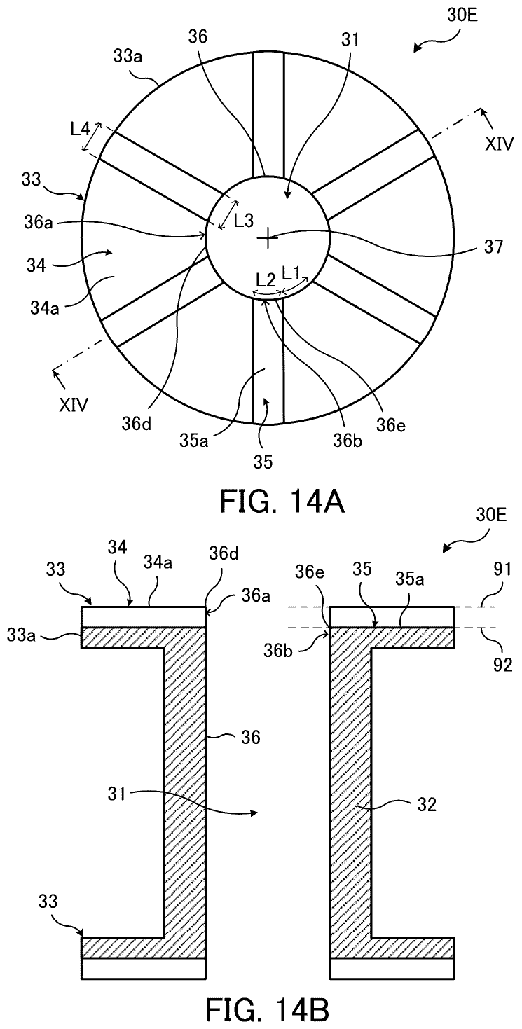

FIGS. 14A and 14B are views for describing an example sleeve according to a fifth embodiment. FIG. 14A is a main-part plan view schematically illustrating the example sleeve. FIG. 14B is a main-part sectional view schematically illustrating the example sleeve. FIG. 14B is a sectional view taken along a line XIV-XIV of FIG. 14A.

For example, a sleeve 30E as illustrated in FIGS. 14A and 14B is disposed as a sleeve 30 disposed on the insulated circuit substrate 10 in the semiconductor device 1 as illustrated in FIG. 2.

The sleeve 30E is configured to have a flange 33 with a plurality (six as an example) of protrusions 34 and a plurality (six as an example) of recesses 35 at each of both opening ends of a cylindrical portion 32 thereof. The flanges 33 at both opening ends have the same configuration. The plurality of protrusions 34 have the same shape, and the plurality of recesses 35 have the same shape.

In a plan view as seen from one opening end of the cylindrical portion 32, each protrusion 34 is provided in the flange 33 such as to extend from a first outer edge portion 36a in the inner surface 36 of a hole 31 to the outer periphery 33a of the flange 33. Each protrusion 34 has a top surface 34a that is continuous with the inner surface 36 in the first outer edge portion 36a. In the sleeve 30E, the first outer edge portion 36a has a bent portion that is continuous with the top surface 34a. The end 36d of the inner surface 36 in the first outer edge portion 36a is located in a first plane 91 (FIG. 14B) including the top surface 34a. In the plan view as seen from the one opening end of the cylindrical portion 32, the protrusions 34 are arranged to radially extend in a direction from the center 37 (FIG. 14A) of the hole 31 toward the outer periphery 33a of the flange 33. In the plan view as seen from the one opening end of the cylindrical portion 32, the protrusions 34 are arranged to be rotationally symmetric with respect to the center 37 of the hole 31 as an axis of symmetry. As an example, six protrusions 34 are arranged to be 60° rotationally symmetric with the center 37 of the hole 31 as the axis of symmetry.

In the plan view as seen from the one opening end of the cylindrical portion 32, each recess 35 is provided in the flange 33 such as to extend from a second outer edge portion 36b in the inner surface 36 of the hole 31 to the outer periphery 33a of the flange 33. Each recess 35 has a bottom surface 35a that is continuous with the inner surface 36 in the second outer edge portion 36b. In the sleeve 30E, the second outer edge portion 36b has a bent portion that is continuous with the bottom surface 35a. The end 36e of the inner surface 36 in the second outer edge portion 36b is located in a second plane 92 (FIG. 14B) including the bottom surface 35a. In the plan view as seen from the one opening end of the cylindrical portion 32, the recesses 35 are arranged to radially extend in a direction from the center 37 (FIG. 14A) of the hole 31 toward the outer periphery 33a of the flange 33. In the plan view as seen from the one opening end of the cylindrical portion 32, the recesses 35 are arranged to be rotationally symmetric with respect to the center 37 of the hole 31 as an axis of symmetry. As an example, six recesses 35 are arranged to be 60° rotationally symmetric with the center 37 of the hole 31 as the axis of symmetry. Each recess 35 is provided such that the depth measured from the top surface 34a of a protrusion 34 to the bottom surface 35a of the recess 35 is 0.055 mm or less.

In addition, in the sleeve 30E, for example, in the plan view as seen from the one opening end of the cylindrical portion 32, the protrusions 34 and recesses 35 are provided in the flange 33 such that the sum of the lengths L1 (FIG. 14A) of the first outer edge portions 36a is greater than or equal to the sum of the lengths L2 (FIG. 14A) of the second outer edge portions 36b.

In the sleeve 30E, for example, in the plan view as seen from the one opening end of the cylindrical portion 32, each recess 35 is provided in the flange 33 such that the length L3 (FIG. 14A) of a straight line connecting both ends of the recess 35 in the second outer edge portion 36b that is continuous with the bottom surface 35a of the recess 35 is equal to the length L4 (FIG. 14A) of a straight line connecting both ends of the recess 35 in the outer periphery 33a of the flange 33. That is, each recess 35 extends from the second outer edge portion 36b in the inner surface 36 of the hole 31 to the outer periphery 33a of the flange 33, with a constant width.

The sleeve 30E configured as above provides the same effects as the sleeve 30A described earlier in the first embodiment. More specifically, since the flange 33 is provided with the recesses 35 each extending from the hole 31 to the outer periphery 33a, gas generated during the soldering of the sleeve 30E is exhausted to the outside of the flange 33 through the recesses 35, which effectively prevents the scattering of the solder 80 caused by an increase in gas pressure. Since the protrusions 34 each extending from the hole 31 to the outer periphery 33a are arranged to be rotationally symmetric with respect to the center 37 of the hole 31 as the axis of symmetry, the posture of the sleeve 30E is stabilized during the soldering, and thus the sleeve 30E is prevented from being inclined.

In addition, in the sleeve 30E, the protrusions 34 and recesses 35 each extend from the hole 31 to the outer periphery 33a of the flange 33. In other words, the top surfaces 34a of the protrusions 34 extend to the first outer edge portions 36a of the hole 31, and the bottom surfaces 35a of the recesses 35 extend to the second outer edge portions 36b of the hole 31. Therefore, in detecting the position of the center 37 of the hole 31 prior to the insertion of an external terminal 40, the first outer edge portions 36a that are continuous with the top surfaces 34a of the protrusions 34, which are less affected by shadows, out of the first outer edge portions 36a (bent portions) and second outer edge portions 36b (bent portions) of the hole 31 are recognized with high accuracy through the binarization processing of an image of the flange 33. That is, the ambiguity of the boundaries between the first outer edge portions 36a of the hole 31 and the top surfaces 34a of the protrusions 34 due to the effects of shadows is mitigated. This achieves highly accurate image recognition to detect the positions of the first outer edge portions 36a of the hole 31 and subsequently detect the contour of the hole 31 on the basis of the information on the positions of the first outer edge portions 36a. The image recognition accuracy of the first outer edge portions 36a and the image recognition accuracy of the contour of the hole 31 to be detected thereafter are improved by setting the sum of the lengths L1 of the first outer edge portions 36a to greater than or equal to the sum of the lengths L2 of the second outer edge portions 36b. Also, by radially arranging more protrusions 34 and more recesses 35 in the flange 33, it becomes possible to reduce the effects of shadows caused by illumination light coming from various directions, thereby achieving highly accurate image recognition of the contour of the hole 31.

The highly accurate image recognition of the contour of the hole 31 allows for precise detection of the position of the center 37 of the hole 31 with minimizing a deviation from its actual position. In inserting the first end 41 of the external terminal 40 into the detected position of the center 37 with the automatic insertion machine, the external terminal 40 is prevented from being inclined. This results in reducing the possibility of damage, insertion failure, or another due to a collision of the second end 42 of the external terminal 40 when the second end 42 is inserted in a circuit substrate or the like.

In the sleeve 30E described in the fifth embodiment, the first outer edge portions 36a in the inner surface 36 of the hole 31 that are continuous with the protrusions 34 of the flange 33 have a bent portion. Alternatively, the first outer edge portions 36a may be configured to have a curved portion, as in the sleeve 30B described earlier as an example in the second embodiment.

Further, in the sleeve 30E described in the fifth embodiment, the second outer edge portions 36b in the inner surface 36 of the hole 31 that are continuous with the recesses 35 of the flange 33 have a bent portion. Alternatively, the second outer edge portions 36b may be configured to have a curved portion, as in the sleeve 30C described earlier as an example in the third embodiment.

Still further, in the sleeve 30E described in the fifth embodiment, all the first outer edge portions 36a and second outer edge portions 36b in the inner surface 36 of the hole 31 that are continuous with the protrusions 34 and recesses 35 of the flange 33 have a bent portion. Alternatively, all the first outer edge portions 36a and second outer edge portions 36b may be configured to have a curved portion, as in the sleeve 30D described earlier as an example in the fourth embodiment.

### Sixth Embodiment

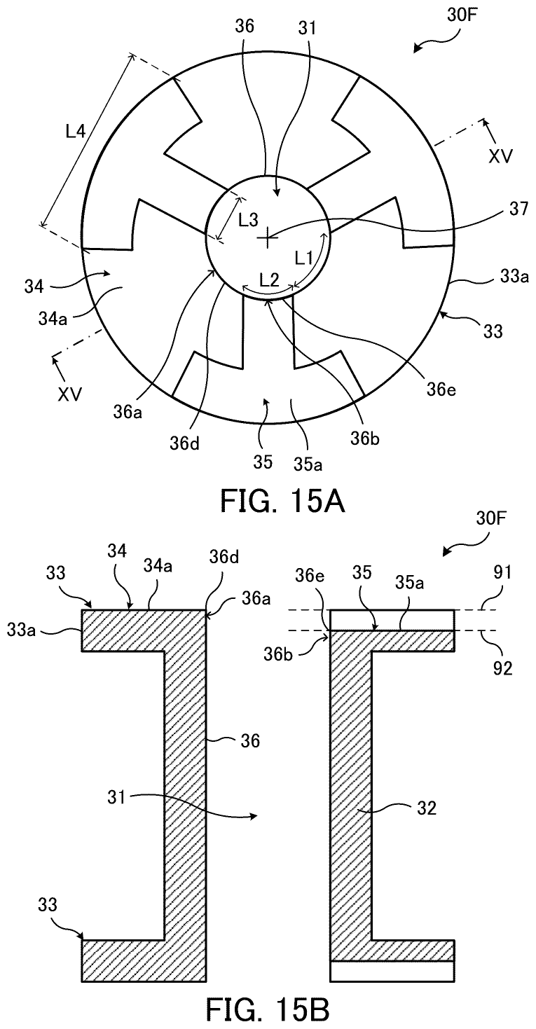

FIGS. 15A and 15B are views for describing an example sleeve according to a sixth embodiment. FIG. 15A is a main-part plan view schematically illustrating the example sleeve. FIG. 15B is a main-part sectional view schematically illustrating the example sleeve. FIG. 15B is a sectional view taken along a line XV-XV of FIG. 15A.

For example, a sleeve 30F as illustrated in FIGS. 15A and 15B is disposed as a sleeve 30 disposed on the insulated circuit substrate 10 in the semiconductor device 1 as illustrated in FIG. 2.

The sleeve 30F is configured to have a flange 33 with a plurality (three as an example) of protrusions 34 and a plurality (three as an example) of recesses 35 at each of both opening ends of a cylindrical portion 32 thereof. The flanges 33 at both opening ends have the same configuration. The plurality of protrusions 34 have the same shape, and the plurality of recesses 35 have the same shape.

In a plan view as seen from one opening end of the cylindrical portion 32, each protrusion 34 is provided in the flange 33 such as to extend from a first outer edge portion 36a in the inner surface 36 of a hole 31 to the outer periphery 33a of the flange 33. Each protrusion 34 has a top surface 34a that is continuous with the inner surface 36 in the first outer edge portion 36a. In the sleeve 30F, each first outer edge portion 36a has a bent portion that is continuous with the top surface 34a. The end 36d of the inner surface 36 in the first outer edge portion 36a is located in a first plane 91 (FIG. 15B) including the top surface 34a. In the plan view as seen from the one opening end of the cylindrical portion 32, the protrusions 34 are arranged to be rotationally symmetric with respect to the center 37 (FIG. 15A) of the hole 31 as an axis of symmetry. As an example, three protrusions 34 are arranged to be 120° rotationally symmetric with the center 37 of the hole 31 as the axis of symmetry.

In the plan view as seen from the one opening end of the cylindrical portion 32, each recess 35 is provided in the flange 33 such as to extend from a second outer edge portion 36b in the inner surface 36 of the hole 31 to the outer periphery 33a of the flange 33. Each recess 35 has a bottom surface 35a that is continuous with the inner surface 36 in the second outer edge portion 36b. In the sleeve 30F, each second outer edge portion 36b has a bent portion that is continuous with the bottom surface 35a. The end 36e of the inner surface 36 in the second outer edge portion 36b is located in a second plane 92 (FIG. 15B) including the bottom surface 35a. In the plan view as seen from the one opening end of the cylindrical portion 32, the recesses 35 are arranged to be rotationally symmetric with respect to the center 37 (FIG. 15A) of the hole 31 as an axis of symmetry. As an example, three recesses 35 are arranged to be 120° rotationally symmetric with the center 37 of the hole 31 as the axis of symmetry. Each recess 35 is provided such that the depth measured from the top surface 34a of a protrusion 34 to the bottom surface 35a of the recess 35 is 0.055 mm or less.

In addition, in the sleeve 30F, for example, in the plan view as seen from the one opening end of the cylindrical portion 32, the protrusions 34 and recesses 35 are provided in the flange 33 such that the sum of the lengths L1 (FIG. 15A) of the first outer edge portions 36a is greater than or equal to the sum of the lengths L2 (FIG. 15A) of the second outer edge portions 36b.

In the sleeve 30F, for example, in the plan view as seen from the one opening end of the cylindrical portion 32, each recess 35 has a planar shape that extends from a second outer edge portion 36b to a midpoint with a constant first width and then extends from the midpoint to the outer periphery 33a of the flange 33 with a second width greater than the first width in the direction from the center 37 of the hole 31 toward the outer periphery 33a. In the sleeve 30F, each recess 35 is also considered to have a substantially T shape in the plan view as seen from the one opening end of the cylindrical portion 32. In each recess 35 having such a planar shape, the length L3 (FIG. 15A) of a straight line connecting both ends of the recess 35 in the second outer edge portion 36b that is continuous with the bottom surface 35a of the recess 35 is less than or equal to the length L4 (FIG. 15A) of a straight line connecting both ends of the recess 35 in the outer periphery 33a of the flange 33 in the plan view as seen from the one opening end of the cylindrical portion 32.

In the flange 33 of the sleeve 30F, the protrusions 34 whose planar shape depends on the planar shape of the recesses 35 are arranged to sandwich the recesses 35 having the above planar shape (or to be sandwiched between the recesses 35).

The sleeve 30F configured as above provides the same effects as the sleeve 30A described earlier in the first embodiment. More specifically, since the flange 33 is provided with the recesses 35 each extending from the hole 31 to the outer periphery 33a, gas generated during the soldering of the sleeve 30F is exhausted to the outside of the flange 33 through the recesses 35, which effectively prevents the scattering of the solder 80 caused by an increase in gas pressure. Since the protrusions 34 each extending from the hole 31 to the outer periphery 33a are arranged to be rotationally symmetric with respect to the center 37 of the hole 31 as the axis of symmetry, the posture of the sleeve 30F is stabilized during the soldering, and thus the sleeve 30F is prevented from being inclined.

Further, in the sleeve 30F, each recess 35 has a planar shape that has an increased width starting at the midpoint in the direction from the center 37 of the hole 31 toward the outer periphery 33a of the flange 33, i.e., a planar shape in which the length L3 of a straight line connecting both ends of the recess 35 in the second outer edge portion 36b is less than or equal to the length L4 of a straight line connecting both ends of the recess 35 in the outer periphery 33a, in the plan view as seen from the one opening end of the cylindrical portion 32. With this configuration, the space between the flange 33 and a conductive layer (conductive layer 12, conductive layer 13, or conductive layer 14) of the insulated circuit substrate 10 expands, which results in an increased amount of solder 80 between the flange 33 and the conductive layer of the insulated circuit substrate 10 and thus enhances the bonding strength.

In addition, in the sleeve 30F, the protrusions 34 and recesses 35 each extend from the hole 31 to the outer periphery 33a of the flange 33. In other words, the top surfaces 34a of the protrusions 34 extend to the first outer edge portions 36a of the hole 31, and the bottom surfaces 35a of the recesses 35 extend to the second outer edge portions 36b of the hole 31. Therefore, in detecting the position of the center 37 of the hole 31 prior to the insertion of an external terminal 40, the first outer edge portions 36a that are continuous with the top surfaces 34a of the protrusions 34, which are less affected by shadows, out of the first outer edge portions 36a (bent portions) and second outer edge portions 36b (bent portions) of the hole 31 are recognized with high accuracy through the binarization processing of an image of the flange 33. That is, the ambiguity of the boundaries between the first outer edge portions 36a of the hole 31 and the top surfaces 34a of the protrusions 34 due to the effects of shadows is mitigated. This achieves highly accurate image recognition to detect the positions of the first outer edge portions 36a of the hole 31 and subsequently detect the contour of the hole 31 on the basis of the information on the positions of the first outer edge portions 36a. The image recognition accuracy of the first outer edge portions 36a and the image recognition accuracy of the contour of the hole 31 to be detected thereafter are improved by setting the sum of the lengths L1 of the first outer edge portions 36a to greater than or equal to the sum of the lengths L2 of the second outer edge portions 36b.

The highly accurate image recognition of the contour of the hole 31 allows for precise detection of the position of the center 37 of the hole 31 with minimizing a deviation from its actual position. In inserting the first end 41 of the external terminal 40 into the detected position of the center 37 with the automatic insertion machine, the external terminal 40 is prevented from being inclined. This results in reducing the possibility of damage, insertion failure, or another due to a collision of the second end 42 of the external terminal 40 when the second end 42 is inserted in a circuit substrate or the like.

This embodiment describes, as an example, the recesses 35 that have a substantially T-shaped planar shape that has an increased width starting from a midpoint in the direction from the center 37 of the hole 31 toward the outer periphery 33a of the flange 33, in the plan view as seen from the one opening end of the cylindrical portion 32. However, the planar shape of the recesses 35 is not limited to this shape. Any planar shape may be used for each recess 35, as long as the length L3 (FIG. 15A) of a straight line connecting both ends of the recess 35 in the second outer edge portion 36b that is continuous with the bottom surface 35a of the recess 35 is less than or equal to the length L4 (FIG. 15A) of a straight line connecting both ends of the recess 35 in the outer periphery 33a of the flange 33 in the plan view as seen from the one opening end of the cylindrical portion 32. For example, the recesses 35 may have a planar shape such as an approximately trapezoidal shape in the plan view, or a planar shape that widens stepwise in the direction from the center 37 of the hole 31 toward the outer periphery 33a of the flange 33.

In this connection, in the sleeve 30F described in the sixth embodiment, the first outer edge portions 36a in the inner surface 36 of the hole 31 that are continuous with the protrusions 34 of the flange 33 have a bent portion. Alternatively, the first outer edge portions 36a may be configured to have a curved portion, as in the sleeve 30B described earlier as an example in the second embodiment.

Further, in the sleeve 30F described in the sixth embodiment, the second outer edge portions 36b in the inner surface 36 of the hole 31 that are continuous with the recesses 35 of the flange 33 have a bent portion. Alternatively, the second outer edge portions 36b may be configured to have a curved portion, as in the sleeve 30C described earlier as an example in the third embodiment.

Still further, in the sleeve 30F described in the sixth embodiment, all the first outer edge portions 36a and second outer edge portions 36b in the inner surface 36 of the hole 31 that are continuous with the protrusions 34 and recesses 35 of the flange 33 have a bent portion. Alternatively, all the first outer edge portions 36a and second outer edge portions 36b may be configured to have a curved portion, as in the sleeve 30D described earlier as an example in the fourth embodiment.

Still further, in the sleeve 30F described in the sixth embodiment, the protrusions 34 and recesses 35 of the flange 33 may be radially arranged in the direction from the center 37 of the hole 31 toward the outer periphery 33a of the flange 33 in the plan view as seen from the one opening end of the cylindrical portion 32, as in the sleeve 30E described earlier as an example in the fifth embodiment.

### Seventh Embodiment

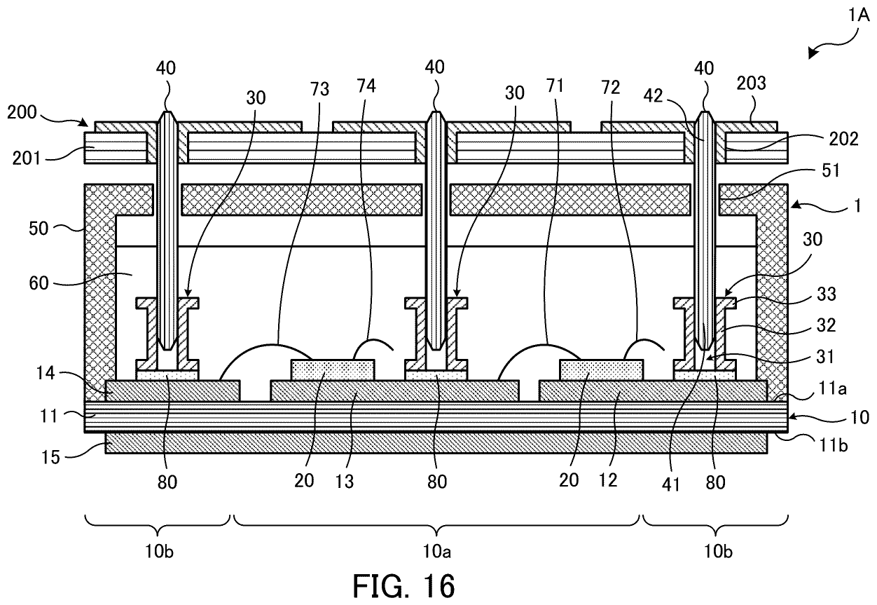

FIG. 16 is a view for describing an example semiconductor device according to a seventh embodiment. FIG. 16 is a main-part sectional view schematically illustrating the example semiconductor device.

The semiconductor device 1A illustrated in FIG. 16 includes a semiconductor device 1 (here, referred to as a “semiconductor module 1” for convenience) as illustrated in FIG. 2 and a circuit substrate 200 connected to the semiconductor module 1.

As described earlier with respect to FIG. 2, the semiconductor module 1 includes the insulated circuit substrate 10, semiconductor elements 20, sleeves 30, external terminals 40, case 50, and sealing resin 60. The insulated circuit substrate 10 includes the insulating board 11, the conductive layers 12, 13, and 14 disposed on one principal surface 11a of the insulating board 11, and the conductive layer 15 disposed on the other principal surface 11b of the insulating board 11. Semiconductor elements 20 that form an: inverter circuit section are disposed at predetermined positions on the conductive layers 12, 13, and 14 using a bonding material such as a solder, wires 71 to 74, and others. In addition, the sleeves 30 are disposed at predetermined positions on the conductive layers 12, 13, and 14 using the solder 80.

For example, any of the sleeves 30A, 30B, 30C, 30D, 30E and 30F described earlier in the first to sixth embodiments is disposed as a sleeve 30 disposed on the insulated circuit substrate 10 in the semiconductor module 1. The first end 41 of an external terminal 40 is inserted into the sleeve 30. In addition, the case 50 is provided to cover the side of the insulated circuit substrate 10 where the semiconductor elements 20 and sleeves 30 are disposed. The second end 42 of the external terminal 40 opposite to the first end 41 thereof inserted into the sleeve 30 is drawn to the outside through an opening 51 of the case 50. Inside the case 50, the insulated circuit substrate 10 and the sealing resin 60 sealing the semiconductor elements 20, sleeves 30, and others disposed on the insulated circuit substrate 10 are arranged. In the semiconductor module 1 configured as

above, the second end 42 of the external terminal 40 drawn to the outside of the case 50 is connected to the circuit substrate 200. The circuit substrate 200 includes an insulating board 201, connection holes 202 penetrating through the insulating board 201, and circuit patterns 203 provided on the front surface of the insulating board 201 and the inner walls of the connection holes 202. The connection holes 202 of the circuit substrate 200 are provided at positions corresponding to the external terminals 40 of the semiconductor module 1. By inserting the second end 42 of an external terminal 40 of the semiconductor module 1 into a connection hole 202 of the circuit substrate 200, the second end 42 is connected to the circuit pattern 203 provided on the inner wall of the connection hole 202. In this connection, the second end 42 of the external terminal 40 may have such a press-fit structure as to enable the second end 42 to be inserted into and connected to the connection hole 202. In addition, the second end 42 may be connected using a solder or the like after being inserted into the connection hole 202. By doing so, the semiconductor module 1 is electrically connected to the circuit substrate 200 via the external terminal 40.

For example, any of the sleeves 30A, 30B, 30C, 30D, 30E, and 30F as described earlier in the first to sixth embodiments is disposed as a sleeve 30 of the semiconductor module 1. With the sleeve 30, the center position of the hole 31 is detectable with high accuracy through the banalization processing of an image captured from the side where the flange 33 is located. The first end 41 of the external terminal 40 is inserted into the detected center position of the hole 31 with the automatic insertion machine. The accurate detection of the center position of the hole 31 prevents the external terminal 40 from being inclined when the first end 41 of the external terminal 40 is inserted into the hole 31. As a result, a positional misalignment between the second end 42 of the external terminal 40 drawn to the outside of the case 50 and the connection hole 202 of the circuit substrate 200 is minimized. Consequently, a collision between the second end 42 of the external terminal 40 and the circuit substrate 200 during the insertion of the second end 42 into the connection hole 202 of the circuit substrate 200 is prevented. This reduces the possibility of damage to the external terminal 40 or the circuit substrate 200, insertion failure in which the second end 42 is not properly inserted into the connection hole 202, and others. As a result, the high-quality semiconductor device 1A is obtained.

The flanges 33 at both opening ends in the sleeve 30 have the same shape, irrespective of whether each flange 33 is located closer to the insulated circuit substrate 10 or the circuit substrate 200. This eliminates the need to manage which one of the flanges 33 at both opening ends is to be placed closer to the insulated circuit substrate 10 or the circuit substrate 200, which is able to reduce the manufacturing cost. In the above-described sleeve 30, the flanges 33 at both opening ends are both able to be joined to the solder 80 using flux. In addition, the flanges 33 at both opening ends are both formed to have the same shape that is appropriate for the insertion of an external terminal 40.

According to one aspect, it is possible to achieve a semiconductor device in which a deviation of the center position of a hole of a sleeve is minimized when the center position is detected through binarization processing of an image of a flange of the sleeve and thus an external terminal is prevented from being inclined when one end of the external terminal is inserted into the sleeve.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulated circuit substrate including an insulating board and a conductive layer disposed on a principal surface of the insulating board; and
a sleeve connected to the conductive layer,
wherein the sleeve includes
a cylindrical portion with a through hole extending in an axial direction of the cylindrical portion that is perpendicular to the principal surface of the insulating board, and
a flange provided at one end of the cylindrical portion, surrounding an opening edge of the through hole,
wherein the flange includes
a plurality of protrusions each protruding in the axial direction away from the insulated circuit substrate, and extending in a radial direction of the cylindrical portion from the opening edge of the through hole to an outer circumferential periphery of the flange, and
a plurality of recesses each recessed in the axial direction toward the insulated circuit substrate, and extending in the radial direction from the opening edge of the through hole to the outer circumferential periphery of the flange, the plurality of recesses being provided respectively alternating with the plurality of protrusions in a circumferential direction of the flange,
wherein each of the plurality of protrusions has a top surface that is continuous from the opening edge of the through hole so as to have a single flat surface parallel to the radial direction, and
wherein each of the plurality of recesses has a bottom surface that is continuous with the opening edge of the through hole so as to have a single flat surface parallel to the radial direction.

2. The semiconductor device according to claim 1, wherein the flange is two flanges, respectively provided at each of opposite ends of the cylindrical portion.

3. The semiconductor device according to claim 1, wherein
the top surfaces of the plurality of protrusions are each entirely flat so that the top surfaces from the opening edge of the through hole to the outer circumferential periphery of the flange are each located at one same plane, and
the bottom surfaces of the plurality of recesses are each entirely flat so that the bottom surfaces from the opening edge of the through hole to the outer circumferential periphery of the flange are each located at another same plane.

4. The semiconductor device according to claim 1, wherein
the plurality of protrusions are arranged to be rotationally symmetric with respect to an axis of the cylindrical portion, and
the plurality of recesses are arranged to be rotationally symmetric with respect to the axis of the cylindrical portion.

5. The semiconductor device according to claim 1, wherein side edges of the top surface of each of the plurality of protrusions from the opening edge of the through hole to the outer circumferential periphery of the flange extend linearly.

6. The semiconductor device according to claim 1, wherein, in a cross section of the flange including an axis of the cylindrical portion, a right angle is formed by a surface of the through hole and each of the top surfaces of the plurality of protrusions, and a right angle is formed by the surface of the through hole and each of the bottom surfaces of the plurality of recesses.

7. The semiconductor device according to claim 1, wherein, in a cross section of the flange including an axis of the cylindrical portion, the top surfaces of the plurality of protrusions are rounded at an opening edge side of the through hole, and a right angle is formed by an internal surface of the through hole and each of the bottom surfaces of the plurality of recesses.

8. The semiconductor device according to claim 1, wherein, in a cross section of the flange including an axis of the cylindrical portion, a right angle is formed by an internal surface of the through hole and each of the top surfaces of the plurality of protrusions, and the bottom surfaces of the plurality of recesses are rounded at an opening edge side of the through hole.

9. The semiconductor device according to claim 1, wherein, in a cross section of the flange including an axis of the cylindrical portion, the top surfaces of the plurality of protrusions are rounded at an opening edge side of the through hole, and the bottom surfaces of the plurality of recesses are rounded at an opening edge side of the through hole.

10. The semiconductor device according to claim 1, wherein each of the top surfaces of the plurality of protrusions has an inner circumferential periphery at the opening edge of the through hole, the inner circumferential periphery having an arc shape with a predetermined radius, a sum of a length of the inner circumferential periphery of each of the top surfaces being greater than 50% of a circumference of a circle with the predetermined radius.

11. The semiconductor device according to claim 2, wherein each of the top surfaces of the plurality of protrusions has an inner circumferential periphery at the opening edge of the through hole, the inner circumferential periphery having an arc shape with a predetermined radius, a sum of a length of the inner circumferential periphery of each of the top surfaces being greater than 50% of a circumference of a circle with the predetermined radius.

12. The semiconductor device according to claim 11, wherein
the top surfaces of the plurality of protrusions are each entirely flat so that the top surfaces from the opening edge of the through hole to the outer circumferential periphery of the flange are each located at one same plane, and
the bottom surfaces of the plurality of recesses are each entirely flat so that the bottom surfaces from the opening edge of the through hole to the outer circumferential periphery of the flange are each located at another same plane.

13. The semiconductor device according to claim 1, wherein, a length of a line passing through two points at which two side edges of the bottom surface of each of the plurality of recesses extend from the opening edge of the through hole to the outer circumferential periphery of the flange respectively intersect the opening edge of the through hole is less than or equal to a length of a line passing through two points at which the two side edges of the bottom surface respectively intersect the outer circumferential periphery of the flange.

14. The semiconductor device according to claim 1, wherein
the insulated circuit substrate includes a center region and an outer peripheral region surrounding the center region in a plan view of the semiconductor device, and
the sleeve is disposed in at least the outer peripheral region out of the center region and the outer peripheral region.

15. The semiconductor device according to claim 2, wherein the flange at another one of the opposite ends of the cylindrical portion of the sleeve is bonded to the conductive layer via a solder.

16. The semiconductor device according to claim 15, further comprising an external terminal including a first end thereof inserted into the through hole of the sleeve from another of the opposite ends of the cylindrical portion.

17. The semiconductor device according to claim 16, further comprising a case accommodating the insulated circuit substrate and the sleeve,
wherein the external terminal includes a second end arranged outside the case, the second end being opposite to the first end.

18. The semiconductor device according to claim 17, further comprising a circuit substrate arranged to face the insulated circuit substrate, the circuit substrate including a connection hole, the second end of the external terminal being inserted into the connection hole.

19. A semiconductor device, comprising:
an insulated circuit substrate including an insulating board and a conductive layer disposed on a principal surface of the insulating board; and
a sleeve connected to the conductive layer,
wherein the sleeve includes
a cylindrical portion with a through hole extending in an axial direction of the cylindrical portion that is perpendicular to the principal surface of the insulating board, and
a flange provided at one end of the cylindrical portion, surrounding an opening edge of the through hole,
wherein the flange includes
a plurality of protrusions each protruding in the axial direction away from the insulated circuit substrate, and extending in a radial direction of the cylindrical portion from the opening edge of the through hole to an outer circumferential periphery of the flange, and
a plurality of recesses each recessed in the axial direction toward the insulated circuit substrate, and extending in the radial direction from the opening edge of the through hole to the outer circumferential periphery of the flange, the plurality of recesses being provided respectively alternating with the plurality of protrusions in a circumferential direction of the flange,
wherein, each of the plurality of protrusions has a top surfaces with an inner circumferential periphery at the opening edge of the through hole, the inner circumferential periphery having shape with a predetermined radius, a sum of a length of the inner circumferential periphery of each of the top surfaces being greater than 50% of a circumference of a circle with the predetermined radius.

20. The semiconductor device according to claim 19, wherein
the plurality of protrusions are arranged to be rotationally symmetric with respect to an axis of the cylindrical portion, and
the plurality of recesses are arranged to be rotationally symmetric with respect to the axis of the cylindrical portion.
